(19) United States
(12) Patent Application Publication
(10) Pub. No.: US 2025/0365923 A1
(43) Pub. Date: Nov. 27, 2025

(54) STORAGE DEVICE, METHOD FOR MANUFACTURING STORAGE DEVICE AND SEMICONDUCTOR DEVICE

(71) Applicant: SwaySure Technology Co., Ltd., Shenzhen (CN)

(72) Inventor: Junhui LI, Shenzhen (CN)

(21) Appl. No.: 19/244,658

(22) Filed: Jun. 20, 2025

(30) Foreign Application Priority Data
Jul. 15, 2024 (CN) 202410948337.9

(51) Int. Cl. H10B 12/00

(52) U.S. Cl. CPC H10B 12/20

(57) ABSTRACT

A storage device includes: a substrate including an insulating surface; a storage cell array including a plurality of storage cells provided on the insulating surface. The plurality of storage cells are repeatedly arranged in a first horizontal direction, a second horizontal direction, and a vertical direction, and the first horizontal direction intersects the second horizontal direction. Each storage cell includes a transistor. The transistor includes a gate insulating layer, a gate structure, and an active layer parallel to the insulating surface. The gate structure includes a gate body portion. The gate body portion includes a first gate. A common source structure and a bit line structure. The bit line structure includes a plurality of bit lines extending in the first horizontal direction. The active layer includes a source end connected to the common source structure and a drain end connected to one of the plurality of bit lines.

### CROSS-REFERENCE TO RELATED APPLICATIONS

This application claims priority to Chinese Patent Application No. 202410948337.9, filed on Jul. 15, 2024, the entire disclosure of which is hereby incorporated herein by reference.

### TECHNICAL FIELD

The present application belongs to the technical field of semiconductors, and particularly relates to a storage device, a method for manufacturing the storage device, and a semiconductor device.

### BACKGROUND

With the miniaturization of technology nodes, the storage cells of Dynamic Random Access Memory (DRAM) are gradually transitioning from the 1 Transistor 1 Capacitor (1T1C) structure to the 1 Transistor 0 Capacitor (1T0C) structure. Due to the adoption of the capacitorless structure, the volume of the storage cell is reduced, and the storage density is increased.

In the existing technology, the storage cells of DRAM are usually arranged repetitively in space to form a three-dimensional stacked structure with a relatively high storage density. However, as the number of stacked layers of the three-dimensional stacked structure increases and the process nodes are miniaturized, the difficulty of the manufacturing process gradually increases.

### SUMMARY

There are provided a storage device, a method for manufacturing the storage device, and a semiconductor device according to embodiments of the present application. The technical solution is as below:

According to a first aspect of embodiments of the present application, there is provided a storage device including:
a substrate, comprising an insulating surface;
a storage cell array, comprising a plurality of storage cells provided on the insulating surface, wherein the plurality of storage cells are repeatedly arranged in a first horizontal direction, a second horizontal direction, and a vertical direction, and the first horizontal direction intersects the second horizontal direction;
wherein each storage cell comprises a transistor, the transistor comprises an active layer, a gate insulating layer, and a gate structure, the gate structure comprises a gate body portion, and the gate body portion comprises a first gate, wherein the active layer is parallel to the insulating surface, the first gate extends along a sidewall of the active layer, and the gate insulating layer is located between the first gate and the active layer; and
the storage device further comprises a common source structure and a bit line structure, the bit line structure comprises a plurality of bit lines, each bit line extends in the first horizontal direction, the active layer comprises a source end and a drain end, the source end is connected to the common source structure, and the drain end is connected to one of the bit lines.

According to a second aspect of embodiments of the present application, there is provided a method for manufacturing a storage device, which includes:
providing a substrate;
preparing a plurality of pairs of film layers stacked in a vertical direction on the substrate, wherein the pair of film layers comprises a semiconductor material layer and a first insulating dielectric layer arranged in sequence in the vertical direction;
etching the plurality of pairs of film layers to form a plurality of first slits repeatedly arranged in a first horizontal direction and a second horizontal direction, wherein the first horizontal direction intersects the second horizontal direction, each first slit vertically penetrate the plurality of pairs of film layers, a second insulating dielectric layer is formed to fill each first slit; in the second horizontal direction, the semiconductor material layer on one side of the first slit is formed into a bit line structure, wherein the bit line structure comprises a plurality of bit lines, and each bit line extends in the first horizontal direction, and a common source structure is formed on one side of each first slit away from the plurality of bit lines;
etching the second insulating dielectric layer in each first slit to form a plurality of first trenches repeatedly arranged in the first horizontal direction and the second horizontal direction; wherein each first trench vertically penetrates the second insulating dielectric layer; the plurality of first trenches correspond one-to-one with the plurality of first slits, and the two sidewalls of each first trench opposite in the first horizontal direction both expose the semiconductor material layer, and in an orthogonal projection onto the substrate, the two sidewalls of the first trench opposite in the second horizontal direction fall into the first trench;
forming a gate material layer on an entire sidewall of the first trench, forming a gate insulating material layer between the gate material layer and a surface of the semiconductor material layer exposed by the first trench, and filling a third insulating dielectric layer in a space surrounded by the gate material layer;
etching the gate material layer to form a plurality of second trenches repeatedly arranged in the first horizontal direction and the second horizontal direction, wherein each second trench penetrates the gate material layer, so that the gate material layer is formed into a first gate structure and a second gate structure spaced in the first horizontal direction; and
filling a fourth insulating dielectric layer in each second trench.

According to a third aspect of embodiments of the present disclosure, there is provided a semiconductor device, which includes:
a substrate;
a transistor stack, comprising a plurality of transistors vertically stacked on the substrate;
wherein the transistor comprises an active layer and a gate electrode, the active layer extends in a horizontal direction, and the gate electrode is located on a sidewall of the active layer, and orthographic projections of all the gate electrodes in one transistor stack on the substrate overlap; and
the gate electrode comprises an integral structure including a gate body portion and a conductor portion, the gate body portion is provided along a length direction of the active layer, and the conductor portion is located on one side of the gate body portion away from the active layer, and the conductor portion is located at both ends of the gate body portion in the horizontal direction.

### BRIEF DESCRIPTION OF THE DRAWINGS

FIG. 1 is a three-dimensional schematic view of a storage device according to an embodiment of the present application.

FIG. 2 is a cross-sectional schematic view of the storage device shown in FIG. 1 at section C1.

FIG. 3 is a cross-sectional schematic view of a transistor in the first horizontal direction and the second horizontal direction according to an embodiment of the present application.

FIG. 4 is a cross-sectional schematic view of a transistor in the first horizontal direction and the second horizontal direction according to another embodiment of the present application.

FIG. 5 is a cross-sectional schematic view of the storage device shown in FIG. 1 at section C2.

FIG. 6 is a cross-sectional schematic view of the storage device shown in FIG. 1 at section C3.

FIG. 7 is a cross-sectional schematic view of the storage device shown in FIG. 1 at section C4.

FIG. 8 is a structural schematic view of a storage device according to an embodiment of the present application.

FIG. 9 is a cross-sectional schematic view of a storage device in the first horizontal direction and the second horizontal direction according to another embodiment of the present application.

FIG. 10 is a flowchart of a method for manufacturing a storage device according to an embodiment of the present application.

FIGS. 11 to 19 are flowcharts of a method for manufacturing the storage device according to an embodiment of the present application.

FIG. 20 is a circuit connection schematic view of a storage cell according to an embodiment of the present application.

### DETAILED DESCRIPTION OF THE EMBODIMENTS

In order to make the purpose, technical solutions, and advantages of the present application clearer, the following further describes the present application in detail with reference to the accompanying drawings and embodiments. The examples of the embodiments are shown in the accompanying drawings, in which the same or similar reference numerals represent the same or similar elements or elements with the same or similar functions throughout. The embodiments described below with reference to the accompanying drawings are exemplary and are only used to explain the present application, and should not be construed as a limitation of the present application. In addition, it should be understood that the specific embodiments described herein are only used to explain the present application, and are not used to limit the present application.

In the description of the present application, it should be understood that the orientation or positional relationship indicated in the description of the orientation and positional relationship is based on the orientation or positional relationship shown in the accompanying drawings, which is only for the convenience of describing the present application and simplifying the description, rather than indicating or implying that the device or element referred to must have a specific orientation, be constructed and operated in a specific orientation, and thus should not be construed as a limitation of the present application.

In addition, the terms “first” and “second” are only used for the purpose of description, and should not be construed as indicating or implying relative importance or implicitly indicating the number of technical features indicated. Thus, the features defined with “first” and “second” may explicitly or implicitly include one or more of the described features. In the description of the present application, “a plurality of” means two or more, unless otherwise specifically defined.

The following disclosure provides many different embodiments or examples for implementing different structures of the present application. In order to simplify the disclosure of the present application, the components and arrangements of specific examples are described below. Of course, they are only examples and are not intended to limit the present application. In addition, the present application may repeatedly refer to numerals and/or reference letters in different examples, and this repetition is for the purpose of simplification and clarity, and does not in itself indicate the relationship between the various embodiments and/or arrangements discussed. In addition, the present application provides examples of various specific processes and materials, but those skilled in the art can be aware of the application of other processes and/or the use of other materials.

In the embodiments of the present application, the technical concept of “layer” refers to a material portion in a region with a thickness. The layer may extend over the entire underlying structure or overlying structure, or may have a smaller extent than the underlying structure or overlying structure. In addition, the layer may be a region of a uniform or non-uniform continuous structure, and its thickness is less than that of the continuous structure.

For example, the layer may be located between any pair of horizontal planes between the top surface and the bottom surface of the continuous structure or at the top surface and the bottom surface of the continuous structure. The layer may extend horizontally, vertically, and/or along a tapered surface. The substrate may be a layer, may include one or more layers therein, and/or may have one or more layers thereon, above it, and/or below it. The layer may include multiple layers. For example, the interconnection layer may include one or more conductor and contact layers (in which interconnect lines and/or via contacts are formed) and one or more dielectric layers.

In the embodiments of the present application, the technical concept of “vertical/vertically” should be understood as perpendicular to the lateral surface of the substrate, and the technical concept of “parallel/parallelly” should be understood as parallel to the lateral surface of the substrate.

Specifically, “vertical” means approximately vertical, for example, means that the angle formed by two straight lines is greater than 80° and less than 100°, so it also includes the angle greater than 85° and less than 95°. In addition, “parallel” means approximately parallel or almost parallel, for example, means that the angle formed by two straight lines is greater than −10° and less than 10°, so it also means the angle is greater than −5° and less than 5°.

The technical concept of “A and B are provided in the same layer” in the embodiments of the present application means that A and B are simultaneously formed through the same patterning process. The technical concept of “the orthographic projection of B is within the scope of the orthographic projection of A” means that the boundary of the orthographic projection of B falls within the boundary range of the orthographic projection of A, or the boundary of the orthographic projection of A overlaps with the boundary of the orthographic projection of B.

The technical concept of “A and B are of an integrated structure” in the embodiments of the present application may mean that there is no obvious fault, slit, or other obvious boundary interfaces at the microstructural level. Generally, a connected film layer patterned on a film layer is of an integrated structure. For example, A and B use the same material to form a film layer and are simultaneously formed into a structure with a connection relationship through the same patterning process.

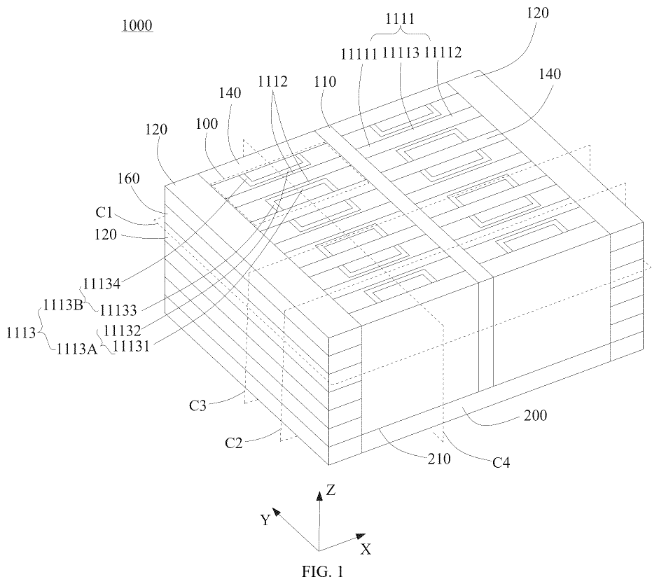

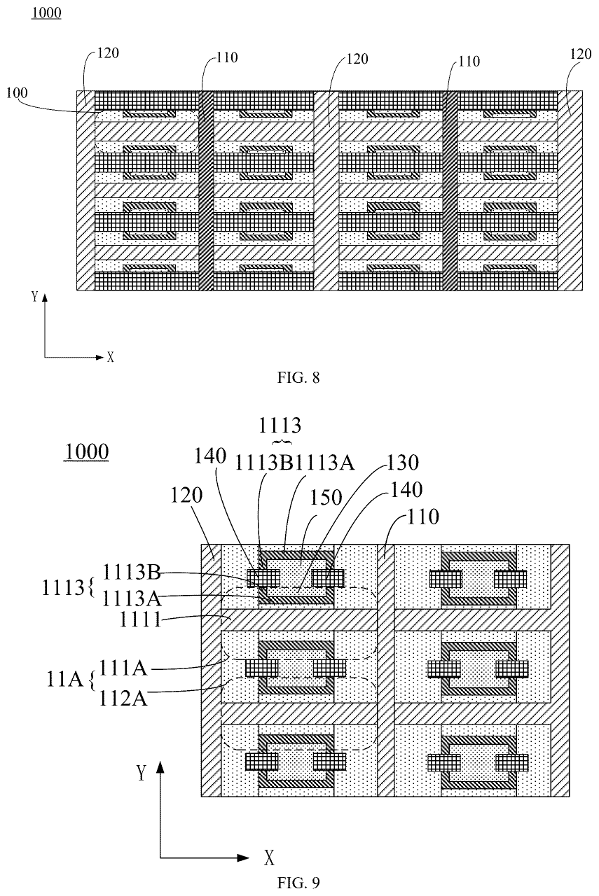

Please refer to FIGS. 1 to 7, the storage device 1000 according to the embodiments of the present application includes:
a substrate 200, including an insulating surface 210;
a storage cell array. The storage cell array includes a plurality of storage cells 100 provided on the insulating surface 210. The plurality of storage cells 100 are repeatedly arranged in a first horizontal direction, a second horizontal direction, and a vertical direction, and the first horizontal direction intersects the second horizontal direction.

Each storage cell 100 includes a transistor. The transistor includes an active layer 1111, a gate insulating layer 1112, and a gate structure 1113. The gate structure 1113 includes a gate body portion 1113A, and the gate body portion 1113A includes a first gate 11131. The active layer 1111 is parallel to the insulating surface 210, the first gate 11131 extends along the sidewall of the active layer 1111, and the gate insulating layer 1112 is located between the gate structure 1113 and the active layer 1111.

The storage device 1000 further includes a common source 110 and a bit line structure 120. The bit line structure 120 includes a plurality of bit lines, each bit line extends in the first horizontal direction. The active layer 1111 includes a source end 11111 and a drain end 11112. The source end 11111 is connected to the common source 110, and the drain end 11112 is connected to one of the bit lines.

Specifically, the substrate 200 may include a semiconductor substrate 200 and an insulating layer located on the side of the semiconductor substrate 200 close to the storage cell array. The surface of the insulating layer away from the semiconductor substrate 200 is formed as the insulating surface 210 of the substrate 200, and the storage cell 100 and the semiconductor substrate 200 are insulated and spaced by the insulating layer.

The substrate 200 may include a semiconductor material, for example, may include at least one of materials such as silicon (e.g., single crystal silicon Si), silicon germanium (SiGe), germanium (Ge), gallium arsenide (GaAs), indium phosphide (InP), and silicon carbide (SiC). Exemplarily, the semiconductor substrate 200 may be a single crystal silicon substrate 200. Optionally, a logic circuit is included in the semiconductor substrate 200.

In one embodiment, the insulating layer may include insulating materials commonly used in the art, such as silicon dioxide (SiO₂), silicon nitride (SiNₓ), etc.

In one embodiment, the substrate 200 may be a single-layer structure, for example, may be a single-layer structure made of at least one of materials such as silicon, germanium, and gallium arsenide.

In another embodiment, the substrate 200 may also be a multi-layer structure, for example, may be a composite substrate 200 including such as a stack of silicon and silicon germanium, a stack of silicon and silicon carbide, silicon on insulator, germanium on insulator, or silicon germanium on insulator, etc.

In other embodiments, the substrate 200 is an insulating substrate, and its upper surface is the insulating surface 210. The insulating substrate may be made of a non-conductive material such as glass, plastic, or a sapphire wafer. Alternatively, the substrate 200 may also be an insulating dielectric material such as silicon dioxide (SiO₂) or silicon nitride (SiNₓ).

It can be understood that both the first horizontal direction and the second horizontal direction are parallel to the substrate, and the vertical direction is perpendicular to the substrate. In the embodiment shown in FIG. 1, the first horizontal direction is the Y-axis direction, the second horizontal direction is the X-axis direction, and the vertical direction is the Z-axis direction. It can be understood that the first horizontal direction, the second horizontal direction, and the vertical direction only need to intersect with each other. Preferably, the first horizontal direction is perpendicular to the second horizontal direction. Preferably, in the embodiment shown in FIG. 1, the X-axis direction is perpendicular to the Y-axis direction, and both the X-axis direction and the Y-axis direction are perpendicular to the Z-axis direction.

In the storage device 1000 in the embodiments of the present application, a plurality of storage cells 100 are repeatedly arranged in the first horizontal direction, the second horizontal direction, and the vertical direction to form a storage cell array. The storage cell 100 has a simple structure, a high storage density, and a simple manufacturing process, and the storage capacity can be increased by continuously increasing the number of stacked layers as needed.

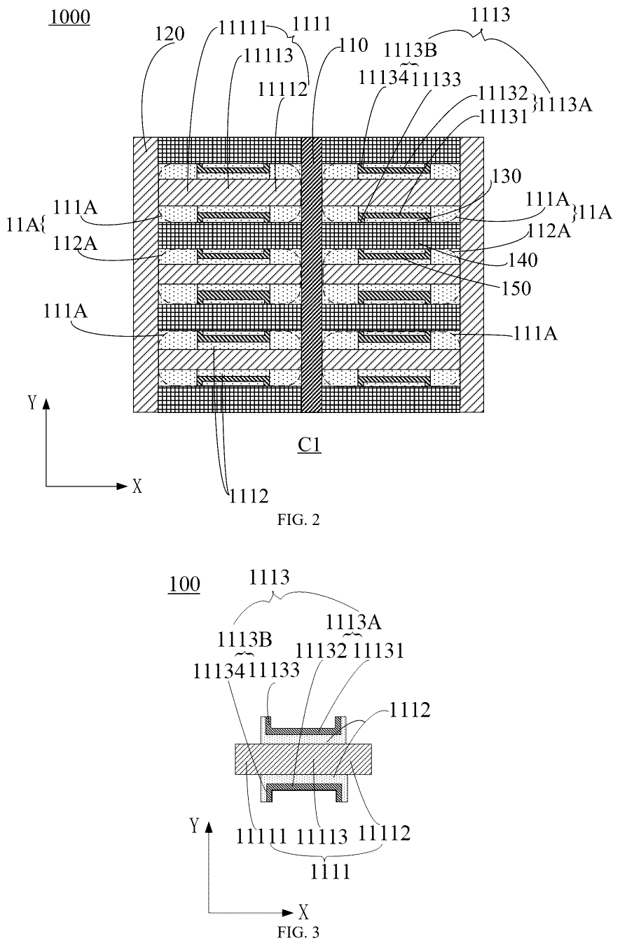

In the embodiments of the present application, it can be regarded that the storage device 1000 is formed by stacking a plurality of storage device layers in the vertical direction. In each storage device layer, a plurality of storage cells 100 are repeatedly arranged in the first horizontal direction and the second horizontal direction to form an array arrangement, as shown in FIG. 2. It can be understood that the array arrangements in the storage device layers are the same.

It should be noted that the “repeatedly arranged” indicates that the storage cell array is a 3D stacked structure, and the structures of the plurality of storage cells 100 may not be completely the same, that is, the structures of the plurality of storage cells 100 may be the same or different.

Exemplarily, as shown in FIG. 1, for two adjacent storage cells 100 in the X direction, their functional structures are symmetrical about the common source 110, that is, they are not completely repeated in space. Exemplarily, the dimensions, materials, and component structures of any two storage cells 100 may be the same or different. Exemplarily, the extension directions of the active layers 1111 of any two storage cells 100 may be the same or different. However, it is not limited to this, and it depends on the specific situation.

FIG. 1 only shows a storage device 1000 formed by 3D stacking of several storage cells 100. It can be understood that the storage device 1000 may include storage device layers with any number of layers, the storage device layers may include any number of storage cells 100, and the storage cells 100 may be arbitrarily distributed and extended along the first horizontal direction, the second horizontal direction, and the vertical direction to meet different storage requirements.

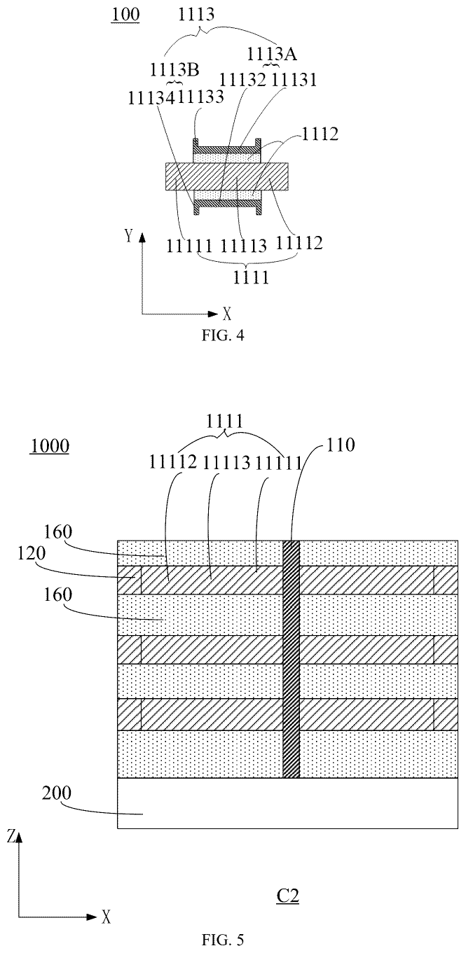

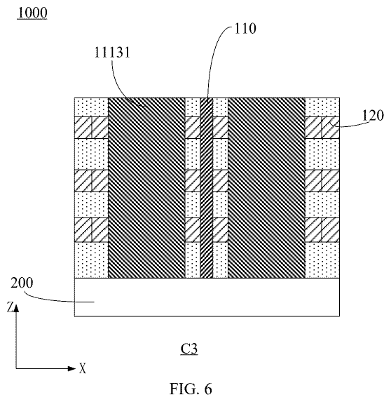

In the embodiments of the present application, the storage device 1000 may be a DRAM storage device, and its basic storage cell 100 is a DRAM storage cell with a 1T0C structure, that is, each storage cell 100 includes a transistor. That is, a single transistor may be the smallest storage cell 100 in the storage device 1000, as shown in FIGS. 3 and 4.

In the storage cell 100, the active layer 1111 is parallel to the insulating surface 210. Exemplarily, the active layer 1111 extends in the second horizontal direction, but it is not limited to this. For example, in other embodiments, the active layer 1111 may extend in a third horizontal direction that intersects both the first horizontal direction and the second horizontal direction. Alternatively, in yet another embodiment, the active layer 1111 may also be a curved shape, depending on the specific situation.

In the storage cell 100, the gate structure 1113 includes a gate body portion 1113A, and the gate body portion 1113A includes a first gate 11131. The first gate 11131 extends along the sidewall of the active layer 1111. It can be understood that the gate body portion 1113A is the part of the gate structure 1113 that can control the active layer 1111, that is, the gate body portion 1113A is the part of the gate structure 1113 that extends along the active layer 1111. The active layer 1111 includes a top surface, a bottom surface, and two sidewalls between the top surface and the bottom surface. The first gate 11131 extends along the sidewall of the active layer 1111 parallel to the substrate 200. The first gate 11131 is approximately perpendicular to the substrate 200, and an orthographic projection of the first gate 11131 on the substrate 200 is located on one side of the active layer 1111.

In the embodiments of the present application, the source end 11111 of the storage cell 100 is connected to the common source structure. The common source structure may be connected to a fixed potential, such as ground. Thus, a fixed potential can be provided for the source end 11111 of the DRAM storage cell 100 of the 1T0C structure.

In one embodiment, the material of the common source structure can be the same as or different from that of the active layer 1111. Exemplarily, the material of the common source structure can be conductive materials such as polysilicon, doped polysilicon, or metal (e.g., tungsten or titanium nitride).

As shown in FIGS. 1, 2, 5, and 6, the common source structure includes at least one common source 110.

The common source structure includes at least one common source 110 vertically provided on the substrate 200. The common source 110 also extends in the first horizontal direction. The common source 110 is connected to a plurality of source ends 11111 adjacent in the vertical direction, and the source ends 11111 adjacent in the first horizontal direction are connected to the same common source 110.

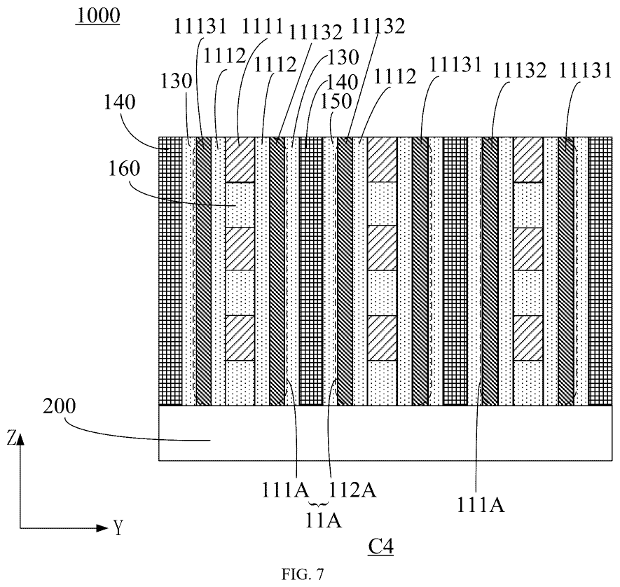

As shown in FIG. 5, the above-mentioned common source 110 can vertically penetrate all the storage device layers. For example, it can vertically penetrate each layer of the above-mentioned multiple layers of storage device layers from top to bottom. Transistors adjacent in the vertical direction in different layers of the storage device layers can be correspondingly connected to the same common source 110.

As shown in FIG. 2, in the same storage device layer, the storage cells 100 are provided in a column in the first horizontal direction. Since the common source 110 extends in the first horizontal direction, each storage cell 100 in the same column of transistors can be correspondingly connected to the same common source 110.

Furthermore, two columns of storage cells 100 adjacent to the common source 110 in the second horizontal direction are symmetrically provided with respect to the common source 110 in terms of functional structure and are both connected to the same common source 110. That is, two columns of storage cells 100 adjacent in the second horizontal direction can share the common source 110.

Thus, the common source 110 can be formed into a plate-like structure extending in the plane formed in the vertical direction and the first horizontal direction. Therefore, the common source 110 can be formed by etching a larger trench and then filling the trench with a conductive material, which can reduce the difficulty of the manufacturing process and has a lower impedance.

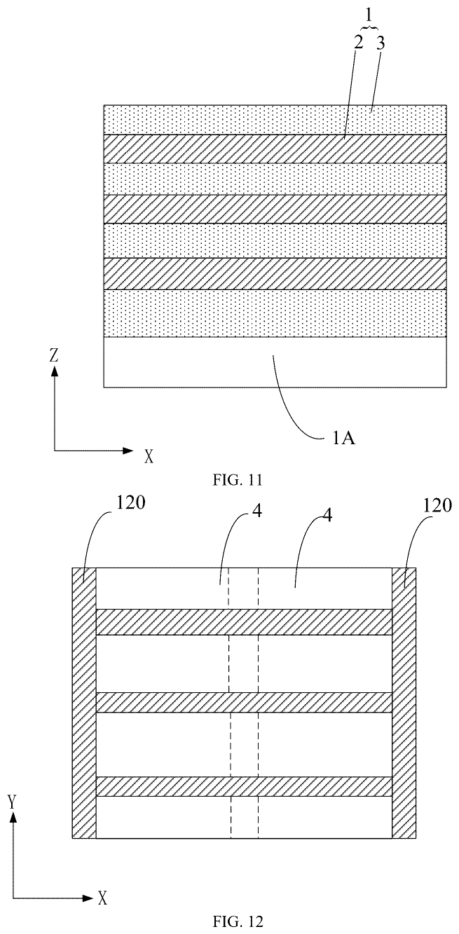

As shown in FIG. 8, the common source structure can include a plurality of common sources 110, and the plurality of common sources 110 are arranged in the second horizontal direction.

However, the present application is not limited to this. In other embodiments not shown in the figures, the common source structure includes a plurality of common sources 110 vertically provided on the substrate 200. The common source 110 is connected to a plurality of source ends 11111 adjacent in the vertical direction, and the source ends 11111 adjacent in the first horizontal direction are connected to different common sources 110. That is, the common source 110 is formed as a columnar vertical conductor penetrating at least two adjacent storage device layers, at this time the common source 110 is regarded as a vertical contact member, and a plurality of vertical contact members are vertically stacked to form the common source structure.

Alternatively, the common source structure can include a plurality of common sources 110 extending in the first horizontal direction. Each common source 110 corresponds to a storage device layer. The adjacent source ends 11111 in the first horizontal direction are connected to the same common source 110, and the adjacent source ends 11111 in the vertical direction are connected to different common sources 110. That is, the common source 110 can be formed as a linear horizontal conductor extending in the first horizontal direction, and a plurality of common sources 110 can be stacked in the vertical direction to reduce the horizontal area of the common source structure.

The present application does not specifically limit the common source structure here, and it can be specifically set according to specific requirements.

As shown in FIGS. 1, 2, and 8, the storage device 1000 includes a bit line structure. The bit line structure includes a plurality of bit lines. The bit lines extend in the first horizontal direction, and the drain end 11112 of the storage cell 100 is connected to the bit line. In the embodiments of the present application, the specified storage cell 100 in the storage cell array can be selected through the cross-positioning of the gate structure 1113 and the bit line.

There maybe a plurality of bit lines included in each storage device layer. The plurality of bit lines included in each storage device layer can be provided at intervals in the second horizontal direction. In the same storage device layer, the storage cells 100 are provided in a column in the first horizontal direction. The bit lines extend in the first horizontal direction, and each storage cell 100 in the same column of transistors can be correspondingly connected to the same bit line.

Furthermore, as shown in FIGS. 2 and 8, in the storage device layer, two columns of storage cells 100 adjacent to the bit line in the second horizontal direction are symmetrically provided with respect to the bit line in terms of functional structure and are both connected to the same bit line. That is, two columns of storage cells 100 adjacent in the second horizontal direction can share the bit line.

In one embodiment, the material of the bit line can be the same as or different from that of the common source 110 and the active layer 1111.

Exemplarily, the material of the bit line can be polysilicon, doped polysilicon, or metal (e.g., tungsten, titanium nitride, etc.), as long as it can conduct electricity to achieve an electrical connection with the source of the transistor.

Exemplarily, the bit line and the active layer 1111 in the above-mentioned transistor can be made of the same material, and they can be connected as a whole.

In one embodiment, the material of the bit line can be the same as that of the active layer 1111, and the bit line and the active layer 1111 in the same storage device layer can be provided by the same semiconductor material layer 2. That is, they can be respectively a part of the same semiconductor material layer 2 and formed as a whole. The semiconductor material layer 2 can be made of N-type polysilicon or P-type polysilicon. For example, it can be made of N-type polysilicon.

Optionally, the doping concentration of the bit line can be higher than that of the active layer 1111.

In the embodiments of the present application, as shown in FIGS. 1, 5 to 7, the storage device 1000 can also include an insulating spacer layer 160. The insulating spacer layer 160 is used to electrically isolate the active layers 1111 and bit lines of transistors in adjacent layers stacked in the vertical direction.

In one embodiment, the material of the insulating spacer layer 160 can be the same as or different from that of the above-mentioned gate insulating layer 1112. Exemplarily, the material of the insulating spacer layer 160 can be insulating materials such as SiO₂, SiNₓ, TEOS (Tetraethoxysilane), or low-dielectric-constant materials.

In the embodiments of the present application, the gate body portion 1113A further includes a second gate 11132. The second gate 11132 extends along the sidewall of the active layer 1111. In the orthogonal projection onto the substrate 200, the first gate 11131 and the second gate 11132 are provided on opposite sides of the active layer respectively. The orthographic projections of the first gate 11131 and the second gate 11132 on the substrate 200 are located on both sides of the active layer 1111 and extend along the sidewall of the active layer 1111.

As shown in FIGS. 2 to 7, the transistor in the storage cell 110 is a double gate transistor, whose two gates are the first gate 11131 and the second gate 11132 respectively.

The first gate 11131 and the second gate 11132 of the gate structure 1113 in the transistor are oppositely provided on the two sides of the active layer 1111 in the horizontal direction, which can improve the control ability of the gate over the channel in the transistor. In particular, for the storage cell with a 1T0C structure, it is more conducive to achieving full depletion of the channel region.

In the embodiments of the present application, the material of the gate structure 1113 can include conductive materials such as metal (e.g., tungsten or titanium nitride). The materials of the first gate 11131 and the second gate 11132 can be the same or different. Preferably, the materials of the first gate 11131 and the second gate 11132 are the same.

Further, the shapes and widths of the first gate 11131 and the second gate 11132 can be the same or different, and they can be completely opposite or only partially opposite. Preferably, the first gate 11131, the second gate 11132, and the active layer 1111 all extend in the second horizontal direction.

As shown in FIGS. 1, 2, and 7, a plurality of storage cells 100 adjacent in the vertical direction form a storage cell stack. In the plurality of storage cells 100 in the storage cell stack, the orthographic projections of the active layer 1111, the gate insulating layer 1112, and the gate structure 1113 on the substrate 200 respectively overlap, and the overlapping parts of the orthographic projections of the gate structures 1113 on the substrate 200 are correspondingly connected.

As an embodiment of the present application, the structures of two adjacent storage cells 100 stacked in the vertical direction are the same, and they are simultaneously fabricated or synchronously patterned. Thus, the orthographic projections of the structures in the upper and lower storage cells 100 on the substrate 200 respectively overlap.

It can be understood that since the storage cells 100 adjacent in the vertical direction are located at different depths, there are certain process errors in their fabrication processes. Therefore, the overlap includes complete overlap and approximate overlap.

It can be understood that the overlapping parts of the orthographic projections of the gate structure 1113 on the substrate 200 are correspondingly connected. That is, the gate structure 1113 includes a gate body portion 1113A and other parts. If the orthographic projections of the gate body portions 1113A on the substrate 200 overlap, the gate body portions 1113A are connected. If the orthographic projections of the other parts on the substrate 200 overlap, the other parts are connected. The gate body portion 1113A includes a first gate 11131 and a second gate 11132. If the orthographic projections of the first gate 11131 and the second gate 11132 on the substrate 200 respectively overlap, the first gate 11131 and the second gate 11132 are connected.

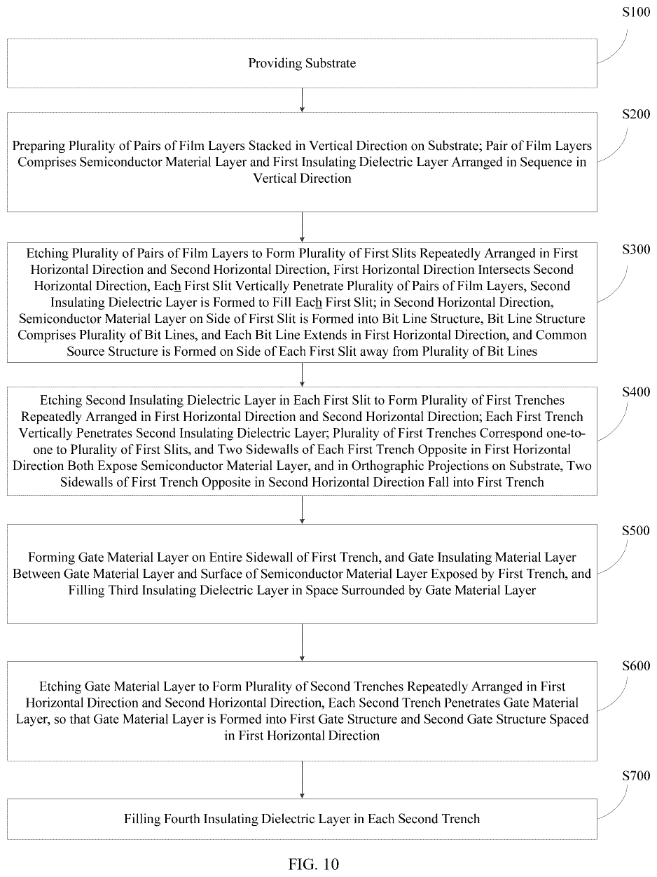

As shown in FIGS. 2 and 7, a plurality of storage cells 100 adjacent in the vertical direction form a storage cell stack. In the plurality of storage cells 100 in the storage cell stack, the orthographic projections of the gate structures 1113 on the substrate 200 respectively overlap. The plurality of storage cell stacks include a first storage cell stack 111A and a second storage cell stack 112A. The first storage cell stack 111A and the second storage cell stack 112A are adjacent in the first horizontal direction and form a storage cell stack group 11A.

In the storage cell stack group 11A, the first gate 11131 of the first storage cell stack 111A is opposite to the first gate 11131 of the second storage cell stack 112A. The gate structure 1113 further includes a conductor portion 1113B. The conductor portion 1113B includes a first conductor portion 11133 integrally formed with the first gate 11131. In the orthographic projection of the first conductor portion 11133 on the substrate 200, the first conductor portion 11133 is located on the side of the first gate 11131 away from the active layer 1111, and the first conductor portion 11133 is located at the two ends of the first gate 11131 in the horizontal direction.

It should be noted that this embodiment does not specifically limit whether the orthographic projections of the active layer 1111 and the gate insulating layer 1112 on the substrate 200 respectively overlap.

As shown in FIGS. 2 and 7, the storage device 1000 includes a plurality of storage cell stacks horizontally distributed on the substrate 200. At least two storage cell stacks adjacent in the first horizontal direction are the first storage cell stack 111A and the second storage cell stack 112A, respectively.

The first storage cell stack 111A and the second storage cell stack 112A are adjacent in the first horizontal direction to form a storage cell stack group 11A. That is, there is no other storage cell stack between the first storage cell stack 111A and the second storage cell stack 112A.

The first gate 11131 of the first storage cell stack 111A is provided opposite to the first gate 11131 of the second storage cell stack 112A. That is, the first gates 11131 of the first storage cell stack 111A and the second storage cell stack 112A are located between the active layers 1111 of the first storage cell stack 111A and the second storage cell stack 112A.

Please refer to FIG. 2, further, in the storage cell 100, the gate structure 1113 further includes a conductor portion 1113B. The conductor portion 1113B includes a first conductor portion 11133 integrally formed with the first gate 11131. In the orthographic projection of the first conductor portion 11133 on the substrate 200, the first conductor portion 11133 is located on the side of the first gate 11131 away from the active layer 1111, and the first conductor portion 11133 is located at the two ends of the first gate 11131 in the horizontal direction. However, it is not limited to this. In some embodiments not shown in the figures, the first conductor portion 11133 is located at one end of the first gate 11131.

Specifically, the first gate 11131 in the embodiment of the present application is roughly in a “C” shape. As shown in FIG. 2, the first gate 11131 extends along the active layer 1111, and the first conductor portion 11133 extends from both ends of the first gate 11131 in the first horizontal direction away from the active layer 1111.

It should be noted that the present application does not limit the included angle between the first gate 11131 and the first conductor portion 11133. The included angle can be an acute angle, an obtuse angle, a right angle, etc. The included angles between different first gates 11131 and first conductor portions 11133 can be the same or different. In some embodiments, the first gate 11131 and the first conductor portion 11133 can also be connected with an arc transition. Moreover, the present application does not specifically limit whether the gate structure 1113 includes the second gate 11132.

In some embodiments, as shown in FIGS. 1 and 2, the storage cell stack group 11A is repeatedly arranged in the first horizontal direction. The embodiments of the present application does not specifically limit whether the gate structure 1113 includes the second gate 11132.

Please continue to refer to FIG. 2, in some embodiments, the gate body portion further includes a second gate 11132. The second gate 11132 is the same as described above and will not be repeated here. The conductor portion 1113B further includes a second conductor portion 11134 integrally formed with the second gate 11132. In the orthographic projection of the second conductor portion 11134 on the substrate 200, the second conductor portion 11134 is located on the side of the second gate 11132 away from the active layer 1111, and the second conductor portion 11134 is located at the two ends of the second gate 11132 in the horizontal direction. However, it is not limited to this. In some embodiments not shown in the figures, the second conductor portion 11134 is located at one end of the second gate 11132.

Specifically, the second gate 11132 in the embodiment of the present application is roughly in a “C” shape. In the embodiment shown in FIG. 2, the second gate 11132 extends along the active layer 1111, and the second conductor portion 11134 extends from both ends of the second gate 11132 in the first horizontal direction away from the active layer 1111.

It should be noted that the present application does not limit the included angle between the second gate 11131 and the second conductor portion 11134. The included angle can be an acute angle, an obtuse angle, a right angle, etc. The included angles between different second gates 11132 and second conductor portions 11134 can be the same or different. In some embodiments, the second gate 11132 and the second conductor portion 11134 can also be connected with an arc transition.

The storage cell stack group 11A is repeatedly arranged in the first horizontal direction, and when the gate structure 1113 includes the second gate 11132 and the second conductor portion 11134 of the second gate 11132, there are oppositely provided “C”-shaped gate electrodes formed between every two storage cell stacks adjacently arranged in the first horizontal direction. It can be understood that the above-mentioned gate electrodes are the whole formed by the first gate 11131 and the first conductor portion 11133, or the whole formed by the second conductor portion 11134 and the second gate 11132. For the second gate 11132, that is, the second gates 11132 are provided oppositely between every two storage cell stack groups 11A adjacently provided in the first horizontal direction.

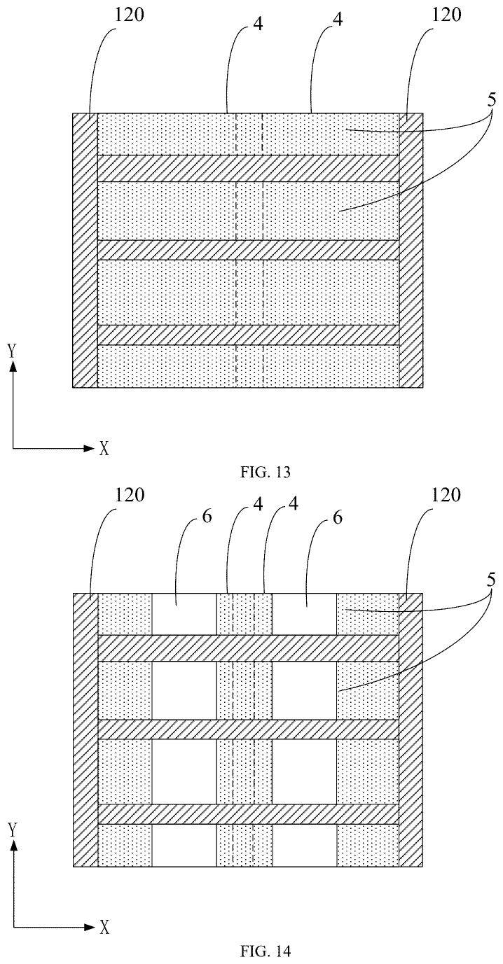

Please continue to refer to FIGS. 2 and 9, further, between the gate structures 1113 of at least one group of adjacent first storage cell stack 111A and second storage cell stack 112A, a first insulating layer 130, a second insulating layer 140, and a third insulating layer 150 are sequentially formed in the direction from the gate structure 1113 of the first storage cell stack 111A to the gate structure 1113 of the second storage cell stack 112A.

The first insulating layer 130 and the third insulating layer 150 are made of the same material. The first insulating layer 130 and the third insulating layer 150 are in contact with the gate body portions 1113A of the first storage cell stack 111A and the second storage cell stack 112A respectively. The second insulating layer 140 is provided between the conductor portions 1113B of the adjacent first storage cell stack 111A and second storage cell stack 112A and is in contact with the conductor portions 1113B of the first storage cell stack 111A and the second storage cell stack 112A.

There is a spacing region between the active layers 1111 of this group of adjacent first storage cell stack 111A and second storage cell stack 112A. At least part of the gate structure 1113 of each of the first storage cell stack 111A and the second storage cell stack 112A is located in the spacing region. This at least part of the gate structure 1113 includes at least part of the gate body portion 1113A and at least part of the conductor portion 1113B, and the parts of the gate structure 1113 located in the spacing region are provided oppositely.

Exemplarily, as shown in FIG. 2, the storage cell 100 includes a first gate 11131. There is a spacing region between the active layers 1111 of a group of adjacent first storage cell stack 111A and second storage cell stack 112A. For the first storage cell stack 111A and the second storage cell stack 112A, the first gate 11131 is provided in the spacing region, and the gate structure 1113 includes a first conductor portion 11133. In the spacing region:

The first insulating layer 130 and the third insulating layer 150 can be fabricated in the same layer and are made of the same material. The first insulating layer 130 and the third insulating layer 150 are in contact with the gate body portion 1113A, that is, the first insulating layer 130 and the third insulating layer 150 are in contact with the first gates 11131 of the first storage cell stack 111A and the second storage cell stack 112A respectively. The second insulating layer 140 is provided between the adjacent first conductor portions 11133 and is in contact with the first conductor portions 11133. That is, the second insulating layer 140 isolates the first conductor portions 11133 located in the spacing region.

However, the present application is not limited to this. In some embodiments, the storage cell 100 further includes a second gate 11132. The second gate 11132 and the second conductor portion 11134 are located in the spacing region. In the spacing region:

The first insulating layer 130 and the third insulating layer 150 can be fabricated in the same layer and are made of the same material. The first insulating layer 130 and the third insulating layer 150 are in contact with the gate body portion 1113A, that is, the first insulating layer 130 and the third insulating layer 150 are in contact with the second gates 11132 of the first storage cell stack 111A and the second storage cell stack 112A respectively. The second insulating layer 140 is provided between the adjacent second conductor portions 11134 and is in contact with the second conductor portions 11134. That is, the second insulating layer 140 isolates the second conductor portions 11134 located in the spacing region.

In the embodiment shown in FIG. 2, in a pair of storage cell stacks adjacent in the first horizontal direction, that is, in the first storage cell stack 111A and the second storage cell stack 112A, the part of the gate structure 1113 located in the spacing region can be fabricated from the same material layer. For example, after a cylindrical conductive film layer extending in the vertical direction is formed in the spacing region, a vertical slit is formed to cut and separate the conductive film layer.

The cutting and separation can be carried out by the etching method. Before etching, the hollow part of the cylindrical conductive film layer is filled with an insulating material, and then the etching process is carried out to form the vertical slit. The above-mentioned slit separates the conductive film layer into two spaced-apart parts, which are respectively formed into the first gate 11131 and the first conductor portion 11133, or the second gate 11132 and the second conductor portion 11134 in this group of adjacent first storage cell stack 111A and second storage cell stack 112A. The remaining insulating material is in contact with the gate body portions 1113A of the first storage cell stack 111A and the second storage cell stack 112A respectively, to form the first insulating layer 130 and the second insulating layer 140. The conductor portions 1113B of the first storage cell stack 111A and the second storage cell stack 112A are opposite to each other across the vertical slit. The vertical slit exposes the opposite conductor portions 1113B. The first insulating layer 130 and the third insulating layer 150 can be completely or partially separated by the vertical slit (as shown in FIG. 9). The second insulating layer 140 fills the vertical slit and is in contact with the conductor portions 1113B.

The first insulating layer 130 and the third insulating layer 150 isolate the gate body portions 1113A of two adjacent storage cells 100 in the first horizontal direction, and the second insulating layer 140 isolates the conductor portions 1113B of two adjacent storage cells 100 in the first horizontal direction.

The first insulating layer 130 and the third insulating layer 150 can be formed in one process. Therefore, they can be made of the same insulating material, such as insulating materials like SiO₂, SiNx, or TEOS. The materials of the first insulating layer 130 and the third insulating layer 150 can be the same as or different from the materials of the above-mentioned gate insulating layer 1112 and insulating spacer layer 160, and the present application does not specifically limit this. The material of the second insulating layer 140 can be the same as or different from the materials of the first insulating layer 130 and the third insulating layer 150.

In some embodiments, the first insulating layer 130 and the third insulating layer 150 can be of single-layer or multi-layer structure, and the second insulating layer 140 can be of single-layer or multi-layer structure. The present application does not specifically limit this.

Further, the first insulating layer 130 and the third insulating layer 150 can be completely or partially separated by the vertical slit. Specifically, in the orthographic projections on the substrate 200: the first insulating layer 130 and the third insulating layer 150 are separately provided on both sides of the second insulating layer 140 (FIG. 2); or, the first insulating layer 130 and the third insulating layer 150 are partially connected (FIG. 9).

As shown in FIG. 9, the above-mentioned slit can also be only formed between two opposite conductor portions 1113B (two first conductor portions 11133 or two second conductor portions 11134) in two adjacent storage cells 100 in the second horizontal direction. That is, the slit only cuts the originally connected gate structures 1113 in two adjacent storage cells 100 in the first horizontal direction and partially extends into the insulating material. That is, the first insulating layer 130 and the third insulating layer 150 are partially connected. It can be understood that even if the first insulating layer 130 and the third insulating layer 150 are partially connected, in the direction from the gate structure 1113 of the first storage cell stack 111A to the gate structure 1113 of the second storage cell stack 112A, the first insulating layer 130, the second insulating layer 140, and the third insulating layer 150 are still sequentially arranged between the gate structures 1113 of this group of adjacent first storage cell stack 111A and second storage cell stack 112A.

Further, between the gate structures 1113 of this group (that is, at least one group) of adjacent first storage cell stack 111A and second storage cell stack 112A, in the orthographic projection on the substrate 200, the first insulating layer 130 is formed in the region surrounded by the gate body portion 1113A and the conductor portion 1113B of the first storage cell stack 111A, and the second insulating layer 140. The side of the first insulating layer 130 extending along the conductor portion 1113B of the first storage cell stack 111A is also adjacent to the second insulating layer 140. The third insulating layer 150 is formed in the region surrounded by the gate body portion 1113A and the conductor portion 1113B of the second storage cell stack 112A, and the second insulating layer 140. The side of the third insulating layer 150 extending along the conductor portion 1113B of the second storage cell stack 112A is also adjacent to the second insulating layer 150.

Please refer to FIG. 16, when etching to form the vertical slit to cut and separate the conductive film, the etching can include an anisotropic etching in the first step and a wet etching in the second step.

The anisotropic etching in the first step forms a pre-trench 10A. The pre-trench 10A penetrates through the conductive film and the insulating material filled in the hollow part of the cylindrical conductive film layer. The pre-trench 10A has basically cut and separated the conductive film, and the insulating material filled in the hollow part of the cylindrical conductive film layer is patterned into the first insulating layer 130 and the third insulating layer 150.

The first insulating layer 130 is formed in the space surrounded by the pre-trench 10A and the conductive film on the side of the first storage cell stack 111A. The part of the conductive film extending along the active layer 1111 of the first storage cell stack 111A is formed as the gate body portion 1113A of the first storage cell stack 111A. The end surface of the first insulating layer 130 away from the gate body portion 1113A of the first storage cell stack 111A and the end surface of the conductive film on the side of the first storage cell stack 111A away from its gate body portion 1113A are formed as a continuous surface, and this continuous surface is exposed to the pre-trench 10A.

Similarly, the third insulating layer 150 is formed in the space surrounded by the pre-trench 10A and the conductive film on the side of the second storage cell stack 112A. The part of the conductive film extending along the active layer 1111 of the second storage cell stack 112A is formed as the gate body portion 1113A of the second storage cell stack 112A. The end surface of the third insulating layer 150 away from the gate body portion 1113A of the second storage cell stack 112A and the end surface of the conductive film on the side of the second storage cell stack 112A away from its gate body portion 1113A are formed as a continuous surface, and this continuous surface is exposed to the pre-trench 10A.

In order to completely cut and separate the conductive film and avoid short-circuiting between the conductor portions 1113B of this group of adjacent first storage cell stack 111A and second storage cell stack 112A, the second step of wet etching is performed. The conductor film exposed by the pre-trench 10A is selectively etched to form the gate structures 1113 of the first storage cell stack 111A and the second storage cell stack 112A.

Compared with the previous continuous surface, the end surface of the conductive film exposed by the pre-trench 10A recedes due to the wet etching, so that the surfaces of the first insulating layer 130 and the third insulating layer 150 that were originally in contact with the conductor film are exposed. The pre-trench 10A expands to form a slit for filling the second insulating layer 140, and the exposed surfaces are formed to be in contact with the second insulating layer 140, as shown in FIG. 16.

Thus, in the orthographic projection on the substrate 200, the side of the first insulating layer 130 extending along the conductor portion 1113B of the first storage cell stack 111A is also adjacent to the second insulating layer 140, and the side of the third insulating layer 150 extending along the conductor portion 1113B of the second storage cell stack 112B is also adjacent to the second insulating layer 140.

It should be noted that the second insulating layer 140 can be an insulating material layer or an air slit with an insulating function. The present application does not specifically limit the composition of the second insulating layer 140. In a preferred embodiment, as shown in FIG. 2, the second insulating layer 140 integrally spaces the first insulating layer 130 and the third insulating layer 150, making the size of the slit where the second insulating layer 140 is located relatively large, which can reduce the process difficulty.

Furthermore, the second insulating layer 140 includes a low dielectric constant (Low K) material. That is, the second insulating layer 140 can be made of a material with a dielectric constant lower than 3.9, which is beneficial to reducing the parasitic capacitance between transistors, including reducing the coupling between the gate structures 1113 of two adjacent storage cells 100 in the first horizontal direction.

In particular, in this embodiment, the gate structures 1113 of two adjacent storage cells 100 in the first horizontal direction include the conductor portion 1113B, and the distance between the closest conductor portions 1113B in two adjacent storage cells 100 in the first horizontal direction is smaller than that between the closest gate body portions 1113A. Therefore, when the material selected for the second insulating layer 140 includes a low dielectric constant material, it is more obvious to reduce the coupling between the gate structures 1113 of two adjacent storage cells 100 in the first horizontal direction.

Further, based on the above technical solutions, the transistor in the embodiment of the present application can be a junctionless field-effect transistor. Therefore, there is no need to perform patterned doping on the source and drain of the transistor, which can simplify the process flow and save production costs.

In the embodiment of the present application, the active layer 1111 is parallel to the insulating surface 210, that is, the active layer 1111 is perpendicular to the vertical direction, and its material includes polysilicon, and preferably, its material includes N-type doped polysilicon. However, it is not limited to this, and the specific material of the active layer 1111 can be set according to actual needs.

Furthermore, in the embodiment of the present application, the transistor is a junctionless transistor. That is, the active layer 1111 also includes a channel region 11113 located between the source end 11111 and the drain end 11112, and the conduction types of the source end 11111, the drain end 11112, and the channel region 11113 are the same. In the storage cell 100, the channel region 11113 is provided corresponding to the first gate 11131 and the second gate 11132. That is, the channel region 11113 is located between the first gate 11131 and the second gate 11132, and the width of the channel region 11113 in the direction from the first gate 11131 to the second gate 11132 is less than 40 nm.

It should be noted that for the active layer 1111 whose material is polysilicon or N-type doped polysilicon, the width of the channel region is less than 40 nm. For the active layer 1111 whose material is not polysilicon, the width of the channel region 11113 can have different ranges.

The width of the channel region 11113 in the direction from the first gate 11131 to the second gate 11132 refers to the distance between the two side surfaces of the channel region 11113 in the first horizontal direction. Since the width of the channel region 11113 in the direction from the first gate 11131 to the second gate 11132 is made to be less than 40 nm, the transistor can become a storage cell 100 with a 1T0C structure, and the storage cell 100 can be read and written.

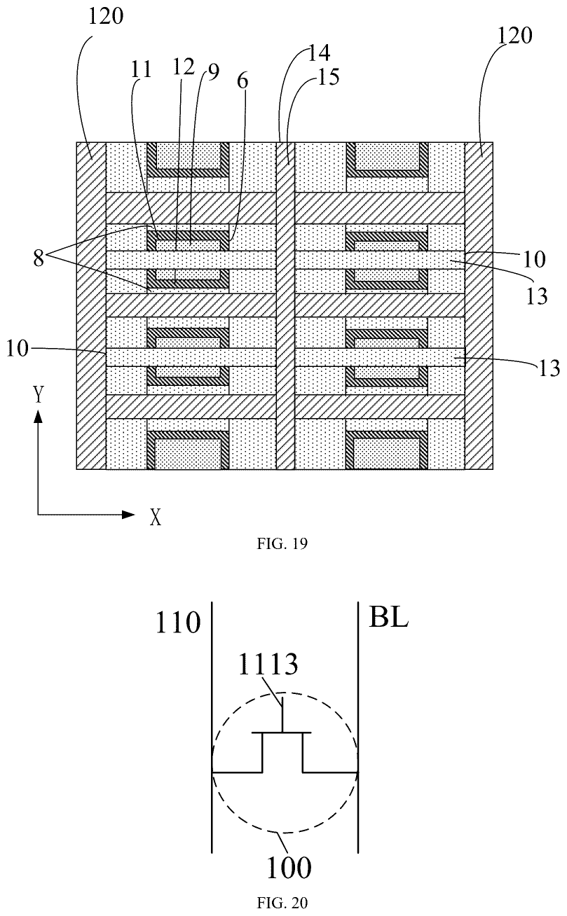

Exemplarily, for the storage cell 100 including a junctionless transistor and the active layer 1111 whose material includes N-type doped polysilicon proposed in the embodiment of the present application, a method for reading and writing operations is proposed. Referring to FIG. 20, the method includes:

applying a negative voltage to the gate structure 1113 and applying a positive voltage to the drain end through the bit line BL. Holes accumulate in the channel region, and the threshold voltage of the transistor decreases, the “write 1” operation is completed; applying a positive voltage to the gate structure 1113 and applying a negative voltage to the drain end through the bit line BL. Carrier recombination occurs in the channel region, and the threshold voltage of the transistor recovers, the “write 0” operation is completed; when a read voltage is applied to the gate structure 1113, due to the difference in the threshold voltage caused by the write operation, drain currents of different magnitudes are generated, so that the “0” and “1” states can be distinguished in the read operation.

Exemplarily, the width of the channel region 11113 can be 30 nm, 20 nm, or 10 nm, etc. In addition, the cross-sectional shape of the channel region 11113 perpendicular to the second horizontal direction can be a geometric shape such as a circle, a square, a rectangle, a hexagon, or an octagon, and the present application does not specifically limit this.

The gate insulating layer 1112 is provided between the gate structure 1113 and the active layer 1111 (channel region 11113) of the transistor, and its material can include SiO₂ or high dielectric constant materials, etc., and the present application does not specifically limit this. Exemplarily, the material of the active layer 1111 contains silicon, such as polysilicon, N-type or P-type doped polysilicon, etc. The gate insulating layer 1112 can be formed by oxidizing the surface including the above silicon-containing material. The unoxidized silicon-containing material layer forms the active layer 1111, which can make the gate insulating layer 1112 only formed on the sidewall of the active layer 1111, and can also make the width of the channel region 11113 smaller than that of at least one of the source end 11111 and the drain end 11112, but it is not limited to this.

As shown in FIG. 7, in some embodiments, an insulating material layer can also be deposited on the surface of the active layer 1111 to form the gate insulating layer 1112, which can make the gate insulating layers 1112 of the plurality of storage cells 100 formed into an integral structure.

Furthermore, as an embodiment of the present application, in the gate structure 1113:

The first gate 11131 and the second gate 11132 are electrically connected to achieve synchronous control of the first gate 11131 and the second gate 11132 in the gate structure 1113; and/or

The first gate 11131 and the second gate 11132 are independently controlled, that is, the first gate 11131 and the second gate 11132 are respectively electrically connected to an external circuit to achieve different controls of the gate structure 1113, which can improve the charge retention ability of the DRAM storage cell 100 with the 1T0C structure; and/or

The first gate 11131 and the second gate 11132 are independently controlled, and the first gate 11131 and the second gate 11132 do not completely overlap on the opposite surfaces, that is, in the storage cell 100, the projections of the first gate 11131 and the second gate 11132 on the active layer 1111 do not completely overlap, which can improve the charge retention ability of the DRAM storage cell 100 with the 1T0C structure.

The electrical connection between the first gate 11131 and the second gate 11132 can be realized by setting a conductive connection structure at the top and/or bottom of the first gate 11131 and the second gate 11132, but it is not limited to this. It can be determined according to the situation as long as the electrical connection therebetween is realized.

The first gate 11131 and the second gate 11132 do not completely overlap on the opposite surfaces. For example, the length of the first gate 11131 is greater than or the length of the second gate 11132, or the projections of the first gate 11131 and the second gate 11132 on the active layer 1111 are staggered in the horizontal direction, and the present application does not specifically limit this.

In the storage device 1000 in the embodiment of the present application, a plurality of DRAM storage cells 100 with the 1T0C structure are repeatedly arranged in the first horizontal direction, the second horizontal direction, and the vertical direction. The storage cell 100 has a simple structure and a high storage density, and the storage capacity can be increased by continuously adding the number of stacked layers as needed, such that the transistor can be a junctionless field-effect transistor, and there is no need for patterned ion implantation of the active layer 1111, reducing the process difficulty and saving production costs. In the transistor of the storage cell 100, the first gate 11131 and the second gate 11132 of the gate structure 1113 are horizontally oppositely provided on both sides of the active layer 1111, which can improve the control of the gate over the channel in the transistor.

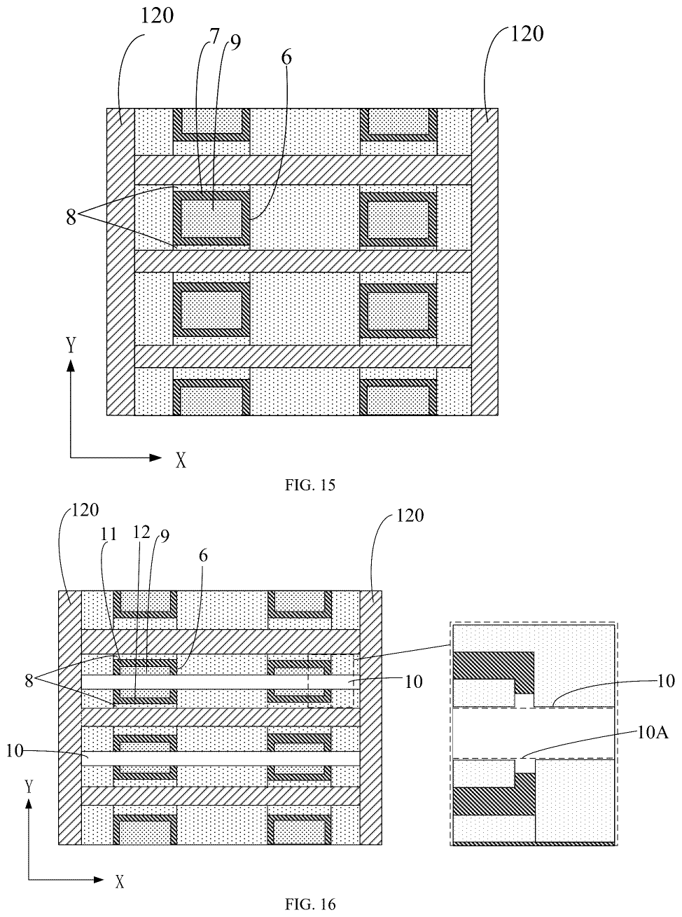

The embodiment of the present application also proposes a method for manufacturing the storage device 1000, which is used to manufacture the storage device 1000 in the previous embodiment. Please refer to FIG. 10, the method for manufacturing the storage device 1000 includes:

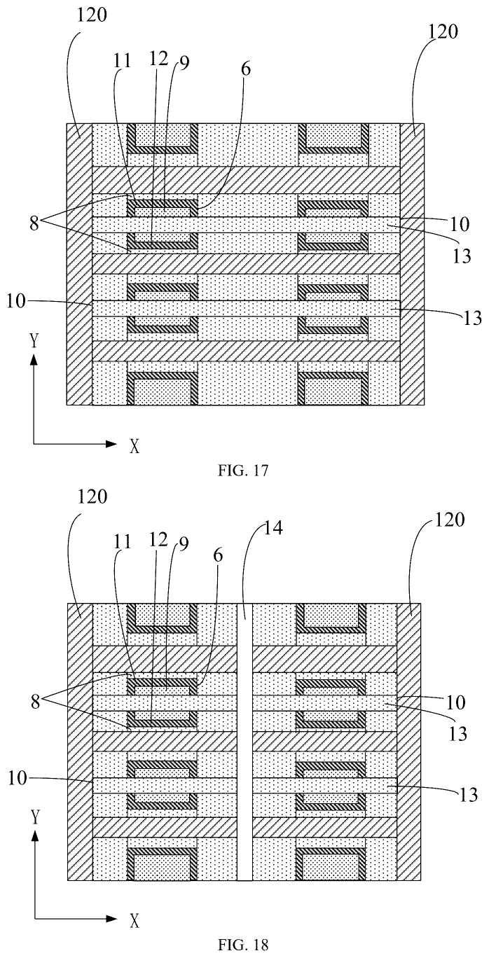

Specifically, in combination with FIG. 11, step S100: Providing a substrate 1A.

In some embodiments, the substrate 1A can be the substrate 200. For the content of the substrate 1A, reference can be made to the description of the substrate 200 in the embodiment of the storage device 1000 above, and it will not be repeated here. However, it is not limited to this. In other embodiments, the substrate can also be a temporary substrate.

Please continue to refer to FIG. 11, step S200: Preparing a plurality of pairs of film layers 1 stacked in the vertical direction on the substrate 1A. The pair of film layers 1 includes a semiconductor material layer 2 and a first insulating dielectric layer 3 arranged in sequence in the vertical direction.

A plurality of pairs of film layers 1 are stacked in the vertical direction to form a stacked structure. That is, the stacked structure includes the first insulating dielectric layer 3 and the semiconductor material layer 2 alternately stacked in the vertical direction.

The formation methods of the semiconductor material layer 2 and the first insulating dielectric layer 3 can include thin film deposition methods such as Chemical Vapor Deposition (CVD), Atomic Layer Deposition (ALD), and Physical Vapor Deposition (PVD).

It can be understood that any suitable materials and deposition processes can be used to form the above first insulating dielectric layer 3 and semiconductor material layer 2.

The material of the semiconductor material layer 2 can be a silicon-containing material, such as a semiconductor material like N-type polysilicon, but it is not limited to this. Oxide semiconductor materials, etc. can also be used for the semiconductor material layer 2, depending on the specific situation.

Taking an oxide semiconductor as an example, the semiconductor material layer 2 can be an Indium Gallium Zinc Oxide (IGZO) layer. It should be noted that the material of the metal oxide can also be ITO, IWO, ZnOₓ, InOₓ, In₂O₃, InWO, SnO₂, TiOₓ, InSnOₓ, ZnₓO_{γ}N_{z}, MgₓZn_{γ}O_{z}, InₓZn_{z}O_{z}, InₓGa_{γ}Zn_{z}Oₐ, ZrₓIn_{γ}Zn_{z}Oₐ, HfₓIn_{γ}Zn_{z}Oₐ, SnₓIn_{γ}Zn_{z}Oₐ, AlₓSn_{γ}In_{z}ZnₐO_{d}, SiₓIn_{γ}Zn_{z}Oₐ, ZnₓSn_{γ}O_{z}, AlₓZn_{γ}Sn_{z}Oₐ, GaₓZn_{γ}Sn_{z}Oₐ, ZrₓZn_{γ}Sn_{z}Oₐ, InGaSiO and other materials, which can be selected according to the actual situation.

In one example, the material of the first insulating dielectric layer 3 can be an insulating material, such as but not limited to SiO₂, and can also be SiNₓ.

In one embodiment, the above stacked structure can be a stacked structure of a SiO₂ layer (first insulating dielectric layer 3)/N-type polysilicon layer (semiconductor material layer 2).

Please refer specifically to FIGS. 12 and 13, step S300: etching multiple pairs of film layers 1 to form multiple first slits 4 repeatedly arranged along the first horizontal direction and the second horizontal direction. The first horizontal direction and the second horizontal direction intersect. The first slit 4 penetrates multiple pairs of film layers 1 along the vertical direction. A second insulating dielectric layer 5 is formed to fill the first slits 4. In the second horizontal direction, the semiconductor material layer 2 on one side of the first slit 4 is formed into a bit line structure 120. The bit line structure 120 includes multiple bit lines, and each bit line extends along the first horizontal direction. A common source structure is formed on the side of the first slit 4 away from the bit line structure.

The first horizontal direction and the second horizontal direction are the same as those described previously, and will not be repeated here.

In the embodiment of the present application, the stacked structure formed by multiple pairs of film layers 1 can be patterned to form the first slit 4 penetrating the stacked structure along the vertical direction, that is, the first slit 4 vertically penetrates each semiconductor material layer 2 and the first insulating dielectric layer 3. For example, an anisotropic etching process (such as a dry etching process like an ion etching process, a reactive ion etching process, etc., or a wet etching process, or an etching process combining dry etching with wet etching) can be used. In the direction perpendicular to the substrate 1A, etching starts from the uppermost semiconductor material layer 2 downward to form the first slits 4, and there are multiple first slits 4. The multiple first slits 4 are repeatedly arranged along the first horizontal direction and the second horizontal direction, that is, the multiple first slits 4 are distributed in an array in the stacked structure. As shown in FIG. 12, the multiple first slits 4 are arranged in columns along the first horizontal direction, and two adjacent columns of first slits 4 in the second horizontal direction are symmetrically distributed.

As shown in FIG. 12, the semiconductor material layer 2 between the adjacent first slits 4 in the first horizontal direction is used to prepare the active layer 1111. In the second horizontal direction, the semiconductor material layer 2 on one side of the first slit 4 is formed into a bit line structure.

It can be understood that the part of the semiconductor material layer 2 is used to prepare the active layer 1111, an end of this part connected to the bit line structure is used to form the drain end, and the end of this part away from the bit line connected to it is used to form the source end, and the source end is used to connect to the common source structure.

The method for manufacturing the storage device 1000 also includes the step of preparing the common source structure. Optionally, the common source is formed on the side of the first slit 4 away from the bit line structure. It can be understood that the common source structure is electrically connected to the source end.

After that, referring to FIG. 13, the second insulating dielectric layer 5 is filled in the first slit 4. The material of the second insulating dielectric layer 5 can be the same as or different from that of the first insulating dielectric layer 3. For example, the material of the second insulating dielectric layer 5 can also be SiO₂.

Please refer specifically to FIG. 14, step S400: etching the second insulating dielectric layer 5 in the first slit 4 to form multiple first trenches 6 repeatedly arranged along the first horizontal direction and the second horizontal direction. Each first trench 6 penetrates the second insulating dielectric layer 5 along the vertical direction. The multiple first trenches 6 correspond to the first slits 4 one by one. Both opposite sidewalls of each first trench 6 in the first horizontal direction expose the semiconductor material layer 2, and in the orthographic projection of the substrate 1A, the opposite sidewalls of the first trench 6 in the second horizontal direction fall within the first slit 4.

Specifically, each first trench 6 penetrates the second insulating dielectric layer 5 along the vertical direction and is located in each first slit 4. Each first trench 6 exposes the semiconductor material layer 2 and the first insulating dielectric layer 3 between two adjacent first trenches 6 in the first horizontal direction. It can be that orthographic projections of the two opposite sidewalls of the first trenches 6 in the first horizontal direction on the substrate 1A overlap with that of the sidewalls of the first slits 4 on the substrate 1A. It can be understood that the semiconductor material layer 2 between two adjacent first trenches 6 in the first horizontal direction is used to form the channel region 11113.

In the orthographic projection on the substrate 1A, the opposite sidewalls of each first trenches 6 in the second horizontal direction fall within the first slit 4. It can be understood that there is a second insulating dielectric layer 5 between the first trench 6 and the bit line structure, and the second insulating dielectric layer 5 is also formed between the first trench 6 and the common source structure to be formed. The second insulating dielectric layer 5 can expose the channel region of the active layer 1111 and cover the source end and the drain end.

In subsequent steps, the first trench 6 is used to prepare the gate structure 1113. Thus, the length of the gate structure 1113 formed in the first trench 6 subsequently, that is, the length of the gate body portion extending horizontally along the active layer 1111, can be controlled by controlling the size of the first trench 6.

In the embodiment of the present application, the etching process can be a dry etching process, a wet etching process, or an etching process combining dry etching with wet etching.

Please refer specifically to FIGS. 15 and 16, step S500: forming a gate material layer 7 on the entire sidewall of the first trench 6, and a gate insulating material layer 8 between the gate material layer 7 and the surface of the semiconductor material layer 2 exposed by the first trench 6, and filling a third insulating dielectric layer 9 in the first trench 6.

It can be understood that filling the third insulating dielectric layer 9 in the first trench 6 means filling the third insulating dielectric layer 9 in the space surrounded by the gate material layer 7.

The gate material layer 7 is used to form the gate structure 1113, and the gate insulating material layer 8 is used to form the gate insulating layer 1112.

The gate insulating material layer 8 is formed at least on the surface of the semiconductor material layer 2 exposed by the first trench 6, as shown in FIG. 15. In one embodiment, the semiconductor material layer 2 contains silicon, such as N-type doped polysilicon. The gate insulating material layer 8 is obtained by oxidizing the semiconductor material layer 2, and the remaining semiconductor material layer 2 is formed into the channel region 11113, so that the gate insulating material layer 8 is only formed on the surface of the active layer exposed by the first trench 6, as shown in FIGS. 4 and 15. Further, since a certain thickness of the semiconductor material layer 2 is consumed, the width of the subsequently formed channel region 11113 can be made smaller than that of the source end 11111 and the drain end 11112 (not shown). In another embodiment, the gate insulating layer material 8 is deposited on the entire sidewall of the first trench 6, and the formed storage cell 100 can be as shown in FIG. 3.

Optionally, the gate material layer 7 is provided on the entire sidewall of the first trench 6, for example, it can be in a vertical cylindrical shape, but it is not limited to this. In some embodiments, the gate material layer 7 can be multiple vertically stacked and spaced rings, depending on the specific situation. Its preparation process can be a commonly used deposition process in the art.

Furthermore, the preparation method of the gate material layer 7 can include: depositing a conductor layer on the entire inner wall of the first trench 6, and removing the part of the conductor layer located at the bottom of the first trench 6. The part of the conductor layer located at the bottom of the first trench 6 can be removed by means of anisotropic etching.

The formation method of the third insulating dielectric layer 9 can be deposition. That is, after the gate material layer 7 is formed on the entire sidewall of the first trench 6, an insulating material is deposited in the remaining first trench 6 surrounded by the gate material layer 7 to form the third insulating dielectric layer 9.

The material of the third insulating dielectric layer 9 can be the same as or different from that of the first insulating dielectric layer 3 and the second insulating dielectric layer 5. Preferably, the material of the third insulating dielectric layer 9 is the same as that of the first insulating dielectric layer 3 and the second insulating dielectric layer 5, that is, the material of the third insulating dielectric layer 9 can also be SiO₂ or SiNₓ.

In addition, the material of the conductor layer can be the same as or different from that of the semiconductor material layer 2. As an embodiment of the present application, the material of the conductor layer is different from that of the semiconductor material layer 2, and the conductor layer can be made of tungsten (W), titanium nitride (TiN), etc.

Please refer specifically to FIG. 16, step S600: etching the gate material layer 7 to form multiple second trenches 10 repeatedly arranged along the first horizontal direction and the second horizontal direction. Each second trench 10 penetrates the gate material layer 7, so that the gate material layer 7 is formed into a first gate structure 11 and a second gate structure 12 spaced apart in the first horizontal direction.

The etching method includes at least anisotropic etching. In order to reduce the difficulty of the etching process, preferably, during the process of etching the gate material layer 7 to form the second trench 10, a part of the third insulating dielectric layer 9 is also etched, that is, the second trench 10 also penetrates the third insulating dielectric layer 9, that is, the second trench cuts the third insulating dielectric layer 9 into a second insulating layer and a third insulating layer that are partially connected.

Preferably, the second trench 10 cuts off the third insulating dielectric layer 9 to form the second insulating layer and the third insulating layer that are spaced apart.

Preferably, during the process of etching the gate material layer 7 to form the second trench 10, a part of the second insulating dielectric layer 5 is also etched, that is, the second trench 10 also penetrates the second insulating dielectric layer 5, which can further reduce the difficulty of the etching process.

In the embodiment of the present application, the second trench 10 extends along the second horizontal direction and penetrates the gate material layer 7 in the vertical direction. It can be understood that the second trench 10 cuts the gate material layer 7 to form two opposite parts in the first horizontal direction, so that the gate material layer 7 is formed into a first gate structure 11 and a second gate structure 12 that are spaced apart in the first horizontal direction.

It can be understood that the first gate structure 11 and the second gate structure 12 respectively belong to two adjacent storage cells in the first horizontal direction.

After the etching is completed, the remaining third insulating dielectric layer 9 is located in the spaces respectively enclosed by the second trenches 10, the first gate structure 11, and the second gate structure 12, to form a second insulating layer and a third insulating layer. That is, during the process of etching to prepare the second trenches, the third insulating dielectric layer 9 covers and protects the parts of the first gate structure 11 and the second gate structure 12 that extend along the surface of the semiconductor material layer 2 exposed by the first trench 6.

It can be understood that when etching to form holes or trenches penetrating the stacked structure, anisotropic etching, such as dry etching, is usually used. As the number of stacked layers in the stacked structure increases, the aspect ratio of the holes or trenches to be formed becomes larger, and the difficulty of the etching process increases. As in the embodiment of the present application, when the aspect ratio of the second trench 10 is high, there is a risk that the anisotropic dry etching cannot completely cut off the gate material layer 7, and there may be a short circuit between the first gate structure 11 and the second gate structure 12, resulting in a decrease in the yield.

Thus, the etching of the gate material layer 7 in step S600 can be achieved through step S610.

Step S610: anisotropically etching the parts of the gate material layer 7 located on the opposite sidewalls of the first trench 6 in the second horizontal direction to form a pre-trench 10A. The pre-trench 10A penetrates the gate material layer 7, and the pre-trench 10A does not expose the parts of the gate material layer 7 located on the opposite sidewalls of the first trench in the first horizontal direction. The wet etching is performed on the gate material layer 7 exposed by the pre-trench 10A to form a first gate structure 11 and a second gate structure 12.

The pre-trench 10A has basically cut the gate material layer 7 to form two opposite parts in the first horizontal direction. Then, one step of the wet etching is performed to ensure that the gate material layer 7 is formed into the first gate structure 11 and the second gate structure 12 that are spaced apart in the first horizontal direction, thereby reducing the short-circuit risk and the difficulty of the etching process. However, it is not limited to this. The process used to etch the gate material layer 7 exposed by the pre-trench 10A to form the first gate structure 11 and the second gate structure 12 can be other isotropic etching processes commonly used in the art, depending on the specific situation.

The parts of the gate material layer 7 located on the opposite sidewalls of the first trench 6 in the second horizontal direction are anisotropically etched to form a pre-trench 10A, and the pre-trench 10A does not expose the parts of the gate material layer 7 located on the opposite sidewalls of the first trench in the first horizontal direction, that is, in the orthographic projection of the substrate 1A, the pre-trench 10A overlaps with the opposite sides of the gate material layer 7 in the second horizontal direction, and forms a gap with the opposite sides of the gate material layer 7 in the first horizontal direction. Thus, when performing wet etching, the etchant can only contact the end of the gate material layer 7 exposed by the pre-trench 10A.

Preferably, the pre-trench 10A also penetrates the third insulating dielectric layer 9, and the wet etching selectively etches the gate material layer 7 without etching the third insulating dielectric layer 9.

Specifically, the anisotropic etching is performed to form a pre-trench 10A. The pre-trench 10A penetrates the gate material layer 7 and the third insulating dielectric layer 9. The pre-trench 10A has basically cut and separated the gate material layer 7, and patterns the third insulating dielectric layer 9 filled in the hollow part of the cylindrical gate material layer 7 into the second insulating layer and the third insulating layer.

The second insulating layer and the third insulating layer are respectively formed in the spaces surrounded by the pre-trench 10A and the gate material layer 7 that is basically cut and separated into two parts. The parts of the gate material layer 7 extending along the opposite sides of the first slit 4 in the first horizontal direction are formed into the gate body portion. The end surfaces of the second insulating layer and the third insulating layer away from the gate body portion in contact with them and the end surface of the gate material layer 7 away from its gate body portion are formed as a continuous surface, and this continuous surface is exposed to the pre-trench 10A, as shown in FIG. 16.

In order to completely cut and separate the gate material layer 7 and avoid a short circuit between the first gate structure 11 and the second gate structure 12, the second step of wet etching is performed to selectively etch the gate material layer 7 exposed by the pre-trench 10A to form the first gate structure 11 and the second gate structure 12.

Compared with the previous continuous surface, the end surface of the gate material layer 7 exposed by the pre-trench 10A recedes due to the wet etching, so that the surfaces of the second insulating layer and the third insulating layer that were originally in contact with the gate material layer 7 are exposed, and the pre-trench 10A expands to form the second slit 10, as shown in FIG. 16.

Preferably, the wet etching does not etch the parts of the first gate structure 11 and the second gate structure 12 that extend along the surface of the semiconductor material layer 2 exposed by the first trench 6. Specifically, the degree of the gate material layer 7 being wet-etched can be achieved by controlling the time of the wet etching. Thus, while reducing the short-circuit risk, it does not affect the gate length.

Therefore, referring to FIGS. 2, 14 and 19, both the first gate structure 11 and the second gate structure 12 include the part extending along the surface of the semiconductor material layer 2 exposed by the first trench 6, that is, both include the gate body portion 1113A, and the part located on the side of the gate body portion 1113A away from the active layer 1111, that is, the conductor portion 1113B. The conductor portion 1113B is located at the two ends of the gate body portion 1113A in the horizontal direction.

Therefore, the semiconductor material layer 2 located between two adjacent first trenches 6 in the first horizontal direction is formed into the active layer 1111. The part of the gate insulating material layer 8 located between the gate structure 1113 and the active layer 1111 is formed into the gate insulating layer 1112. The active layer 1111, the gate insulating layer 1112 and the gate structure 1113 form the storage cell 100 of the storage device 1000. One end of the active layer 1111 is connected to the bit line, and the other end of the active layer 1111 is connected to the common source structure 120. It can be understood that the gate structure 1113 is one of the first gate structure 11 and the second gate structure 12 described above, and the first gate structure 11 and the second gate structure 12 belong to two storage cells 100 respectively.

Please refer specifically to FIG. 17, step S700: filling a fourth insulating dielectric layer 13 in the second trench 10.

The fourth insulating dielectric layer 13 is formed into the first insulating layer.

It should be noted that the above first insulating layer is the second insulating layer 140 in the embodiment of the above storage device 1000 (as shown in FIG. 2). The fourth insulating dielectric layer 13 insulates and isolates the gate structures 1113 of adjacent transistors in the first horizontal direction.

It should be noted that the fourth insulating dielectric layer 13 used to form the first insulating layer can be an insulating material layer or an air slit. The present application does not specifically limit the composition of the fourth insulating dielectric layer 13 and the first insulating layer.

Furthermore, the material of the fourth insulating dielectric layer 13 includes a low dielectric constant material.

Exemplarily, the fourth insulating dielectric layer 13 can be made of a material with a dielectric constant lower than 3.9, which is beneficial to reducing the parasitic capacitance between transistors.

The material of the fourth insulating dielectric layer 13 can be the same as or different from that of the first insulating dielectric layer 3 to the third insulating dielectric layer 9. Furthermore, the material of the fourth insulating dielectric layer 13 is different from that of the first insulating dielectric layer 3 to the third insulating dielectric layer 9.

In the embodiment of the present application, the material of the third insulating dielectric layer 9 can be SiO₂ or SiNₓ, and the material of the fourth insulating dielectric layer 13 is a low dielectric constant material.

Thus, a second insulating layer, a first insulating layer and a third insulating layer are provided between two adjacent gate body portions in the first horizontal direction.

It should be noted that the second insulating layer here is the first insulating layer 130 in the embodiment of the above storage device 1000, and the third insulating layer is the third insulating layer 150 in the embodiment of the above storage device 1000. It can be understood that the second insulating layer and the third insulating layer are formed after the third insulating dielectric layer 9 is patterned.

Furthermore, as an embodiment of the present application, the two opposite surfaces of two adjacent first trenches 6 in the first horizontal direction do not completely overlap.

It can be understood that two adjacent first trenches 6 in the first horizontal direction can be used to form the gate structure 1113 in the same transistor. The gate structure 1113 includes the first gate 11131 and the second gate 11132, thereby making the two opposite surfaces of two adjacent first trenches 6 in the first horizontal direction not completely overlap, and thus the first gate 11131 and the second gate 11132 that do not completely overlap on the opposite surfaces can be formed. The storage cell 100 includes a transistor, and the transistor includes the first gate 11131 and the second gate 11132 that are opposite and do not completely overlap, which is the same as the previous embodiment and will not be repeated here.

In some embodiments, the method of forming the common source structure includes:

Step S310: forming a common source 110, and the common source 110 includes multiple vertical contact members.

The embodiment in which the common source 110 includes vertical contact members is the same as the content in the embodiment of the previous storage device 1000, and will not be repeated here.

In a preferred embodiment of the present application, the common source 110 is a plate-like structure, which extends along the first horizontal direction, that is, it extends parallel to the bit line structure 120. The common source 110 penetrates the stacked structure in the vertical direction and is connected to the semiconductor material layer 2 of each layer.

On the above basis, the method of forming the common source structure includes: etching multiple pairs of film layers 1 to form multiple third slits repeatedly arranged in the second horizontal direction. The third slits extend along the first horizontal direction and penetrate multiple pairs of film layers 1 in the vertical direction. A conductive material is filled in the third slit to form the common source 110. The common source 110 is connected to the semiconductor material layers 2 adjacent in the vertical direction, or the common source 110 is connected to the semiconductor material layer 2 of each layer.

Specifically, as shown in FIGS. 18 and 19, the semiconductor material layer 2 and the fourth insulating dielectric layer 13 are etched to form a third trench 14. The third trench 14 extends along the first horizontal direction, and the third trench 14 penetrates the semiconductor material layer 2 and the fourth insulating dielectric layer 13. A conductive layer is filled in the third trench 14 to form the common source 110.

The embodiment in which the common source 110 includes a plate-like structure is the same as the content in the embodiment of the previous storage device 1000, and will not be repeated here.

It is worth mentioning that although the content of the method for manufacturing the storage device in this embodiment is described in the order of the method steps, in specific implementation, the order of some method steps can be changed. For example, the preparation step of the common source structure can be carried out after step S200 and before any step, and it can be implemented according to specific needs.

In one embodiment, the method of forming the common source structure includes: forming the bit line structure 120 and the common source 110 on the semiconductor material layers 2 on both sides of the first slit 4 in the second horizontal direction respectively.

The embodiment in which the common source 110 includes a horizontal wiring extending along the first direction is the same as the previous embodiment, and will not be repeated here.

The method for manufacturing the storage device in the embodiment of the present application, in addition to having the beneficial effects of the above embodiment of the storage device 1000, can also reduce the short-circuit risk, not affect the gate length, and significantly improve the yield of the storage device 1000.

Although the previous embodiment of the present application proposes a 3D 1T0C DRAM storage device, the above storage device has a C-shaped gate electrode, which can reduce the short-circuit risk. However, in a semiconductor device with a 3D stack where the repeating units include a horizontal channel and a vertical gate, a C-shaped gate can be prepared to reduce the short circuit. Therefore, the present application also proposes the following embodiment of the semiconductor device.

The semiconductor device in the embodiment of the present application includes: a substrate; a transistor stack including multiple transistors vertically stacked on the substrate; the transistor includes an active layer and a gate electrode. The active layer extends in the horizontal direction, and the gate electrode is located on the sidewall of the active layer. The orthographic projections of all the gate electrodes in the transistor stack on the substrate overlap. The gate electrode includes a gate body portion and a conductor portion that are integrated. The gate body portion is provided along the length direction of the active layer. The conductor portion is located on the side of the gate body portion away from the active layer, and the conductor portion is located at the two ends of the gate body portion in the horizontal direction.

The structures such as the gate body portion, the conductor portion, the gate electrode and the transistor stack can be similar to the gate body portion, the conductor portion, the gate structure and the storage cell stack containing only one transistor in the previous embodiment of the storage device, and will not be repeated here.

In some embodiments not shown, the conductor portion can be located at one end of the gate body portion in the horizontal direction.

In the semiconductor device in the embodiment of the present application, the transistor included in the repeating unit can be a JFET or a MOSFET, which is not specifically limited. However, it should be noted that when the transistor is a MOSFET, the transistor also includes a gate insulating layer, and the gate insulating layer is located between the gate body portion and the active layer. It can be understood that the repeating unit can also include other structures besides the transistor described in the previous embodiment.

In the embodiment of the present application, there are multiple transistor stacks, and the multiple transistor stacks are horizontally distributed on the substrate. In the horizontal direction perpendicular to the extension direction of the gate body portion, the gate electrodes of two adjacent transistor stacks are provided oppositely.

It can be understood that the gate electrodes of two adjacent transistor stacks are provided oppositely, that is, the gate electrodes of the two transistor stacks are located between the active layers of the two transistor stacks and are provided face to face, and the gate body portion and the conductor portion are opposite respectively.

Exemplarily, the extension direction of the active layer and the gate body portion is the second horizontal direction, and the horizontal direction perpendicular to the extension direction of the gate body is the first horizontal direction, that is, the gate electrodes of two adjacent transistor stacks in the first horizontal direction are provided oppositely.

In the embodiment of the present application, in adjacent transistor stacks, the oppositely provided gate electrodes are in a “C” shape. The gate electrodes of the transistor stacks can be formed into a “C” shape by specifically implementing the method including step S610 of the manufacturing method of the above storage device, that is, etching to form a pre-trench, so that the gate material layer integrally prepared and used to form the gate electrodes of adjacent transistor stacks is basically disconnected, and then wet etching is carried out to form the gate electrodes of adjacent transistor stacks that are disconnected from each other. Herein is the same as the previous content and will not be repeated here. Thus, while ensuring the disconnection and reducing the short-circuit risk, it does not affect the gate length.

Furthermore, in the embodiment of the present application, the semiconductor device includes a first insulating layer, a second insulating layer and a third insulating layer. In the horizontal direction perpendicular to the extension direction of the gate body portion, the first insulating layer, the second insulating layer and the third insulating layer are sequentially provided between the gate electrodes of two adjacent transistor stacks. The first insulating layer and the third insulating layer are made of the same material, and are in contact with the gate body portions of two adjacent transistor stacks respectively. The second insulating layer is provided between the conductive portions of two adjacent transistor stacks and is in contact with the conductor portions of two adjacent transistor stacks.

Specifically, the first insulating layer and the third insulating layer isolate the gate body portions of two adjacent transistor stacks in the first horizontal direction (that is, the horizontal direction perpendicular to the extension direction of the gate body), and the second insulating layer isolates the conductor portions of two adjacent transistor stacks in the first horizontal direction. The first insulating layer and the third insulating layer can be formed in one process. Therefore, they can be made of the same insulating material, such as insulating materials like SiO₂, SiNₓ or TEOS.

Furthermore, since the method of step S610 in the method for manufacturing the storage device can be used to prepare the gate electrodes, between the gate electrodes of two adjacent transistor stacks, in the orthographic projection on the substrate: the first insulating layer and the third insulating layer are respectively formed in the regions surrounded by the gate electrodes of two adjacent storage cell stacks and the second insulating layer, a side of the first insulating layer extending along the conductor portion in contact with it is also adjacent to the second insulating layer, and the side of the third insulating layer extending along the conductor portion in contact with it is also adjacent to the second insulating layer.

The material of the second insulating layer can be the same as or different from that of the first insulating layer and the third insulating layer. Since the second insulating layer is formed in a different process from the first insulating layer and the third insulating layer, preferably, the material of the second insulating layer is different from that of the first insulating layer and the third insulating layer.

It should be noted that the structures, materials and functions, etc. of the first insulating layer, the second insulating layer and the third insulating layer mentioned in the context of the embodiment of the semiconductor device are basically the same as those of the first insulating layer, the second insulating layer and the third insulating layer mentioned in the embodiment of the above storage device. For other contents of the first insulating layer, the second insulating layer and the third insulating layer that are not mentioned in the embodiment of the semiconductor device, the corresponding contents of the first insulating layer, the second insulating layer and the third insulating layer in the above embodiment of the storage device can be referred to, and will not be described in too much detail here.

Furthermore, in the embodiment of the present application, the first insulating layer and the third insulating layer are separately provided on both sides of the second insulating layer; or the first insulating layer and the third insulating layer are partially connected.

There is a certain spaced region between adjacent transistor stacks, and the gate electrodes of the transistors are included in this spaced region. The part of the gate electrodes located in the spaced region can be prepared from the same material layer. For example, after a cylindrical conductive film layer extending in the vertical direction is formed in the spaced region, a vertical slit is formed to cut and separate the conductive film layer.

The cutting and separation can be carried out by the etching method. Before etching, the hollow part of the cylindrical conductive film layer is filled with an insulating material, and then the etching process is carried out to form a vertical slit. The above-mentioned slit separates the conductive film layer into two spaced parts, which are respectively formed into the gate body portion and the conductor portion of the adjacent transistor stacks. The remaining insulating materials respectively form the first insulating layer and the second insulating layer. The conductor portions of the two transistor stacks are opposite, the vertical slit exposes the opposite conductor portions, the first insulating layer and the third insulating layer can be completely or partially separated by this vertical slit, and the second insulating layer fills this vertical slit and is in contact with the conductor portions.

Exemplarily, the above-mentioned slit can also be only formed between two opposite conductor portions in two adjacent transistor stacks in the second horizontal direction. That is, the slit only cuts the originally connected gate electrodes in two adjacent transistor stacks in the second horizontal direction and partially extends into the insulating material, that is, the first insulating layer and the third insulating layer are partially connected.

In a preferred embodiment, the second insulating layer integrally spaces the first insulating layer and the third insulating layer, making the size of the slit relatively large, which can reduce the process difficulty.

Furthermore, in the embodiment of the present application, the second insulating layer includes a low dielectric constant (Low K) material.

That is, the second insulating layer can be made of a material with a dielectric constant lower than 3.9, which is beneficial to reducing the parasitic capacitance between transistors, including reducing the coupling between the gate electrodes of two adjacent transistors in the horizontal direction.

In particular, in the embodiment of the present application, the gate electrodes of two adjacent transistors in the horizontal direction each includes the conductor portion, and the distance between the closest conductor portions of two adjacent transistors in the horizontal direction is smaller than that between the closest gate body portions. Therefore, when the material selected for the second insulating layer includes a low dielectric constant material, it is more obvious to reduce the coupling between the gate electrodes of two adjacent transistors in the horizontal direction, avoiding crosstalk due to the too close distance between the conductor portions of two adjacent transistors.

Furthermore, in the embodiment of the present application, the overlapping parts of the gate electrodes in their orthographic projections on the substrate are correspondingly connected.

That is, the gate electrodes in the transistor stack are integrally prepared, that is, the gate electrodes of each transistor in the transistor stack are connected together as an integral structure, and the gate electrodes are prepared and formed in one process, such that all the transistors stacked in the vertical direction can be controlled by one gate electrode vertically provided, which can simplify the manufacturing process of the semiconductor device and reduce the manufacturing cost.

In the semiconductor device of the embodiment of the present application, multiple transistors are vertically stacked to form a transistor stack. The transistor has a horizontal channel and a vertical gate. The gates of adjacent transistor stacks can be synchronously prepared, reducing the manufacturing cost, such that the vertical gate includes a gate body portion extending horizontally along the active layer, and conductor portions located at the two ends of the gate body portion in the horizontal direction. The conductor portions are horizontally located on the side of the gate body portion away from the active layer, which can reduce the short-circuit risk between the vertical gates without affecting the gate length.

In the description of this specification, the descriptions referring to the terms “Embodiment 1”, “Embodiment 2” and so on mean that the specific features, structures, materials or characteristics described in combination with the embodiments or examples are included in at least one embodiment or example of the present application. In this specification, the schematic representations of the above terms do not necessarily refer to the same embodiment or example. Moreover, the described specific features, structures, materials or characteristics can be combined in any one or more embodiments or examples in a suitable manner.

The above are only preferred embodiments of the present application and are not intended to limit the present application. Any modifications, equivalent replacements, improvements, etc. made within the spirit and principles of the present application should be included in the protection scope of the present application.

What is claimed is:

1. A storage device, comprising:
a substrate, comprising an insulating surface; and
a storage cell array, comprising a plurality of storage cells provided on the insulating surface, wherein the plurality of storage cells are repeatedly arranged in a first horizontal direction, a second horizontal direction, and a vertical direction, and the first horizontal direction intersects the second horizontal direction;
wherein each storage cell comprises a transistor, the transistor comprises an active layer, a gate insulating layer, and a gate structure, the gate structure comprises a gate body portion, and the gate body portion comprises a first gate, wherein the active layer is parallel to the insulating surface, the first gate extends along a sidewall of the active layer, and the gate insulating layer is located between the first gate and the active layer; and
the storage device further comprises a common source structure and a bit line structure, the bit line structure comprises a plurality of bit lines, each bit line extends in the first horizontal direction, the active layer comprises a source end and a drain end, the source end is connected to the common source structure, and the drain end is connected to one of the plurality of bit lines.

2. The storage device according to claim 1, wherein the gate body portion further comprises a second gate extending along the sidewall of the active layer; and
in an orthogonal projection onto the substrate, the first gate and the second gate are provided on opposite sides of the active layer respectively.

3. The storage device according to claim 1, wherein the plurality of storage cells adjacent in the vertical direction form a storage cell stack; and
in the plurality of storage cells in the storage cell stack, orthographic projections of the active layer, the gate insulating layer, and the gate structure on the substrate respectively overlap, and overlapping parts of orthographic projections of gate structures on the substrate are correspondingly connected.

4. The storage device according to claim 1, wherein the plurality of storage cells adjacent in the vertical direction form a storage cell stack;
in the storage cell stack, orthographic projections of gate structures on the substrate overlap;
the plurality of storage cell stacks comprise a first storage cell stack and a second storage cell stack;
the first storage cell stack and the second storage cell stack are adjacent in the first horizontal direction to form a storage cell stack group;
in one storage cell stack group, the first gate of the first storage cell stack is opposite to the first gate of the second storage cell stack;
the gate structure further comprises a conductor portion, and the conductor portion comprises a first conductor portion integrally formed with the first gate; and
in an orthogonal projection onto the substrate, the first conductor portion is located on one side of the first gate away from the active layer, and is located at both ends of the first gate in the horizontal direction.

5. The storage device according to claim 4, wherein storage cell stack groups are repeatedly arranged in the first horizontal direction.

6. The storage device according to claim 5, wherein the gate body portion comprises a second gate, the second gate extends along the sidewall of the active layer;
in the orthogonal projection onto the substrate, the first gate and the second gate are provided on opposite sides of the active layer, facing each other respectively;
the conductor portion further comprises a second conductor portion integrally formed with the second gate;
in the orthogonal projection onto the substrate, the second conductor portion is located on one side of the second gate away from the active layer, and is located at both ends of the second gate in the horizontal direction; and
between two adjacent memory cell stack groups in the first horizontal direction, the second gates are provided opposite to each other.

7. The storage device according to claim 4, wherein between the gate structures of at least one group of the first storage cell stack and the second storage cell stack adjacent to each other, a first insulating layer, a second insulating layer, and a third insulating layer are sequentially formed in a direction from the gate structure of the first storage cell stack to the gate structure of the second storage cell stack, and materials of the first insulating layer and the third insulating layer are the same; and
the first insulating layer and the third insulating layer respectively contact the gate body portions of the first storage cell stack and the second storage cell stack, the second insulating layer is provided between opposite conductive portions of the first storage cell stack and the second storage cell stack, and the second insulating layer contacts the conductor portions of the first storage cell stack and the second storage cell stack.

8. The storage device according to claim 7, wherein between the gate structures of at least one group of the first storage cell stack and the second storage cell stack adjacent to each other, in the orthogonal projection onto the substrate:
the first insulating layer is formed in a region surrounded by the gate body portion, the conductor portion of the first storage cell stack, and the second insulating layer, and one side of the first insulating layer extending along the conductor portion of the first storage cell stack is also adjacent to the second insulating layer; and
the third insulating layer is formed in a region surrounded by the gate body portion, the conductor portion of the second storage cell stack, and the second insulating layer, and one side of the third insulating layer extending along the conductor portion of the second storage cell stack is also adjacent to the second insulating layer.

9. The storage device according to claim 7, wherein in the orthogonal projection onto the substrate:
the first insulating layer and the third insulating layer are separately provided on two sides of the second insulating layer; or the first insulating layer and the third insulating layer are partially connected.

10. The storage device according to claim 2, wherein the transistor is a junctionless transistor;
the material of the active layer comprises N-type doped polysilicon;
the active layer further comprises a channel region located between the source end and the drain end; and
in the storage cell, the channel region is located between the first gate and the second gate, and a width of the channel region in a direction from the first gate to the second gate is less than 40 nm.

11. The storage device according to claim 1, wherein the common source structure comprises at least one common source vertically provided on the substrate; and
the common source also extends in the first horizontal direction and is connected to source ends of a plurality of active layers adjacent in the vertical direction, and source ends of active layers adjacent in the first horizontal direction are connected to the same common source.

12. A method for manufacturing a storage device, comprising:
providing a substrate;
preparing a plurality of pairs of film layers stacked in a vertical direction on the substrate; wherein the pair of film layers comprises a semiconductor material layer and a first insulating dielectric layer arranged in sequence in the vertical direction;
etching the plurality of pairs of film layers to form a plurality of first slits repeatedly arranged in a first horizontal direction and a second horizontal direction, wherein the first horizontal direction intersects the second horizontal direction, each first slit vertically penetrate the plurality of pairs of film layers, a second insulating dielectric layer is formed to fill each first slit; in the second horizontal direction, the semiconductor material layer on one side of the first slit is formed into a bit line structure, wherein the bit line structure comprises a plurality of bit lines, and each bit line extends in the first horizontal direction, and a common source structure is formed on one side of each first slit away from the plurality of bit lines;
etching the second insulating dielectric layer in each first slit to form a plurality of first trenches repeatedly arranged in the first horizontal direction and the second horizontal direction; wherein each first trench vertically penetrates the second insulating dielectric layer; the plurality of first trenches correspond one-to-one with the plurality of first slits, the two sidewalls of each first trench opposite in the first horizontal direction both expose the semiconductor material layer, and in an orthogonal projection onto the substrate, the two sidewalls of the first trench opposite in the second horizontal direction fall into the first trench;
forming a gate material layer on an entire sidewall of the first trench, forming a gate insulating material layer between the gate material layer and a surface of the semiconductor material layer exposed by the first trench, and filling a third insulating dielectric layer in a space surrounded by the gate material layer;
etching the gate material layer to form a plurality of second trenches repeatedly arranged in the first horizontal direction and the second horizontal direction, wherein each second trench penetrates the gate material layer, so that the gate material layer is formed into a first gate structure and a second gate structure spaced in the first horizontal direction; and
filling a fourth insulating dielectric layer in each second trench.

13. The method for manufacturing the storage device according to claim 12, wherein etching the gate material layer to form the plurality of second trenches repeatedly arranged in the first horizontal direction and the second horizontal direction, wherein each second trench penetrates the gate material layer, so that the gate material layer is formed into the first gate structure and the second gate structure spaced in the first horizontal direction comprises:
anisotropically etching a part of the gate material layer located on the two sidewalls of the first trench opposite in the second horizontal direction to form a pre-trench, wherein the pre-trench penetrates the gate material layer and the pre-trench does not expose the part of the gate material layer located on the two sidewalls of the first trench opposite in the first horizontal direction; and
wet-etching the gate material layer exposed by the pre-trench to form the second trench.

14. The method for manufacturing the storage device according to claim 13, wherein in a step of anisotropically etching the part of the gate material layer located on the two sidewalls of the first trench opposite in the second horizontal direction to form the pre-trench, the third insulating layer is also etched, and the pre-trench also makes the third insulating dielectric layer be formed into a second insulating layer and a third insulating layer at least partially spaced in the first horizontal direction.

15. The method for manufacturing the storage device according to claim 12, wherein the gate material layer formed on the entire sidewall of the first trench comprises:
depositing a conductor layer on an entire inner wall of the first trench and removing a part of the conductor layer located at a bottom of the first trench.

16. The method for manufacturing the storage device according to claim 12, wherein forming the common source structure comprises:
etching the semiconductor material layer to form a third trench extending in the first horizontal direction, wherein the third trench penetrates all the semiconductor material layers; and
filling a conductive layer in the third trench to form a common source structure;
wherein in the second horizontal direction, the common source structure and the bit line structure are respectively located on two sides of the first slit.

17. A semiconductor device, comprising:
a substrate; and
a transistor stack, comprising a plurality of transistors vertically stacked on the substrate;
wherein each transistor comprises an active layer and a gate electrode, the active layer extends in a horizontal direction, and the gate electrode is located on a sidewall of the active layer, and orthographic projections of all gate electrodes in one transistor stack on the substrate overlap; and
the gate electrode comprises an integral structure comprising a gate body portion and a conductor portion, the gate body portion is provided along a length direction of the active layer, and the conductor portion is located on one side of the gate body portion away from the active layer, and the conductor portion is located at both ends of the gate body portion in the horizontal direction.

18. The semiconductor device according to claim 17, wherein a plurality of transistor stacks are horizontally distributed on the substrate;
in a horizontal direction perpendicular to an extension direction of the gate body portion, gate electrodes of two adjacent transistor stacks are oppositely provided.

19. The semiconductor device according to claim 18, wherein the semiconductor device comprises a first insulating layer, a second insulating layer, and a third insulating layer;
in the horizontal direction perpendicular to the extension direction of the gate body portion, the first insulating layer, the second insulating layer, and the third insulating layer are sequentially provided between the gate electrodes of the two adjacent transistor stacks;
the first insulating layer and the third insulating layer are made of the same material and respectively contact the gate body portions of the two transistor stacks; and
the second insulating layer is provided between the conductive portions of the two adjacent transistor stacks and contacts the conductor portions of the two adjacent transistor stacks.

20. The semiconductor device according to claim 19, wherein between gate structures of the two adjacent transistor stacks, in the orthographic projection onto the substrate:
the first insulating layer and the third insulating layer are respectively formed in regions surrounded by the gate electrodes of the two adjacent storage cell stacks and the second insulating layer; and
a side of the first insulating layer extending along the conductor portion in contact with the first insulating layer is also adjacent to the second insulating layer, and a side of the third insulating layer extending along the conductor portion in contact with the third insulating layer is also adjacent to the second insulating layer.
